(19) United States
(12) Patent Application Publication
(10) Pub. No.: US 2026/0013116 A1
(43) Pub. Date: Jan. 8, 2026

(54) SEMICONDUCTOR DEVICE INCLUDING BIT LINES

(71) Applicant: Samsung Electronics Co., Ltd., Suwon-si (KR)

(72) Inventors: Joonyoung Kang, Suwon-si (KR); Kyumin Kim, Suwon-si (KR); Dahee Kim, Suwon-si (KR); Seokhyun Kim, Suwon-si (KR); Hyosun Min, Suwon-si (KR); Junhyung Sim, Suwon-si (KR); Hoin Ryu, Suwon-si (KR); Sunwoo Heo, Suwon-si (KR)

(21) Appl. No.: 19/018,075

(22) Filed: Jan. 13, 2025

(30) Foreign Application Priority Data
Jul. 8, 2024 (KR) 10-2024-0089721

(51) Int. Cl. H10B 12/00

(52) U.S. Cl. CPC H10B 12/482; H10B 12/02; H10B 12/315; H10B 12/50

(57) ABSTRACT

A semiconductor device includes a substrate including a first active area, a plurality of bit lines on the substrate, intersecting with the first active area, extending in a first direction parallel to an upper surface of the substrate, and having a first width in a second direction that intersects with the first direction, a plurality of bit line pads respectively connected to end portions of the plurality of bit lines and having a second width that is greater than the first width in the second direction, a boundary spacer on a sidewall of each of the plurality of bit line pads, and an insulating block on a sidewall of the boundary spacer and between two adjacent bit line pads among the plurality of bit line pads.

### CROSS-REFERENCE TO RELATED APPLICATION

This application is based on and claims priority under 35 U.S.C. § 119 to Korean Patent Application No. 10-2024-0089721, filed Jul. 8, 2024, in the Korean Intellectual Property Office, the disclosure of which is incorporated by reference herein in its entirety.

### BACKGROUND

The inventive concept relates to a semiconductor device, and more particularly, to a semiconductor device including bit lines.

Along with down-scaling of a semiconductor device, the size of an individual fine circuit pattern for implementing the semiconductor device has further decreased. In addition, along with high integration of an integrated circuit device, the line width of a bit line has decreased, and the gap between bit lines has also decreased. Therefore, the difficulty of a process of forming a contact between bit lines has increased.

### SUMMARY

Embodiments of the inventive concept provides a semiconductor device capable of reducing or preventing the occurrence of bit line defects in a process of forming a contact between bit lines.

According to an aspect of the inventive concept, there is provided a semiconductor device including a substrate including a first active area, a plurality of bit lines on the substrate, intersecting with the first active area, extending in a first direction parallel to an upper surface of the substrate, and each having a first width in a second direction that intersects with the first direction, a plurality of bit line pads respectively connected to end portions of the plurality of bit lines and each having a second width that is greater than the first width in the second direction, a boundary spacer on a sidewall of each of the plurality of bit line pads, and an insulating block on a sidewall of the boundary spacer and between two adjacent bit line pads among the plurality of bit line pads.

According to another aspect of the inventive concept, there is provided a semiconductor device including a substrate including a first active area, a plurality of bit lines on the substrate, intersecting with the first active area, extending in a first direction parallel to an upper surface of the substrate, and including a plurality of first bit lines and a plurality of second bit lines alternately arranged in a second direction that intersects with the first direction, a plurality of bit line pads respectively connected to end portions of the plurality of bit lines and including a plurality of first bit line pads respectively connected to first end portions of the plurality of first bit lines and a plurality of second bit line pads respectively connected to second end portions opposite to first end portions of the plurality of second bit lines, a boundary spacer on a sidewall of each of the plurality of bit line pads, and an insulating block on a sidewall of the boundary spacer and between two adjacent bit line pads among the plurality of bit line pads.

According to another aspect of the inventive concept, there is provided a semiconductor device including a substrate including a cell array area, a boundary area, and a peripheral circuit area and including a first active area in the cell array area, a boundary insulating structure in the boundary area of the substrate, a plurality of bit lines disposed in the cell array area of the substrate, intersecting with the first active area, extending in a first direction parallel to an upper surface of the substrate, and each having a first width in a second direction that intersects with the first direction, a plurality of bit line pads respectively connected to end portions of the plurality of bit lines and each having a second width that is greater than the first width in the second direction, a boundary spacer on a sidewall of each of the plurality of bit line pads, a peripheral circuit gate electrode in the peripheral circuit area of the substrate, and an insulating block on a sidewall of the boundary spacer, between two adjacent bit line pads among the plurality of bit line pads, and between each of the plurality of bit line pads and the peripheral circuit gate electrode.

### BRIEF DESCRIPTION OF THE DRAWINGS

Embodiments of the inventive concept will be more clearly understood from the following detailed description taken in conjunction with the accompanying drawings in which:

FIG. 1 is a layout diagram illustrating a semiconductor device according to some embodiments;

FIG. 2 is a magnified view of a portion A of FIG. 1;

FIG. 3 is a cross-sectional view taken along line A1-A1′ of FIG. 2;

FIG. 4 is a cross-sectional view taken along line A2-A2′ of FIG. 2;

FIG. 5 is a cross-sectional view taken along line B1-B1′ of FIG. 2;

FIG. 6 is a cross-sectional view taken along line B2-B2′ of FIG. 2;

FIG. 7 is a magnified view of a portion CX1 of FIG. 3;

FIG. 8 is a magnified view of a portion CX2 of FIG. 4; and

FIGS. 9A, 9B, 9C, 10A, 10B, 11A, 11B, 12, 13A, 13B, 13C, 14A, 14B, 15A, 15B, 16A, 16B, 16C, 17A, 17B, 17C, 18, 19A, 19B, 20A, 20B, 20C, 21A, and 21B are top plan views and cross-sectional views illustrating a method of manufacturing a semiconductor device, according to embodiments.

### DETAILED DESCRIPTION OF THE EMBODIMENTS

Hereinafter, embodiments are described in detail with reference to the accompanying drawings. The same reference numerals are given to the same elements in the drawings, and repeated descriptions thereof are omitted. As used herein, the term “and/or” includes any and all combinations of one or more of the associated listed items. It will be understood that when an element is referred to as being “on,” “attached” to, “connected” to, “coupled” with, “contacting,” etc., another element, it can be directly on, attached to, connected to, coupled with or contacting the other element or intervening elements may also be present. In contrast, when an element is referred to as being, for example, “directly on,” “directly attached” to, “directly connected” to, “directly coupled” with or “directly contacting” another element, there are no intervening elements present. It will be understood that, although the terms “first,” “second,” etc. may be used herein to describe various elements or components, these elements or components should not be limited by these terms. These terms are only used to distinguish one element or component from another element or component. Therefore, a first element or component discussed below could be termed a second element or component without departing from the technical spirit of the present disclosure. It is noted that aspects described with respect to one embodiment may be incorporated in different embodiments although not specifically described relative thereto. That is, all embodiments and/or features of any embodiments can be combined in any way and/or combination.

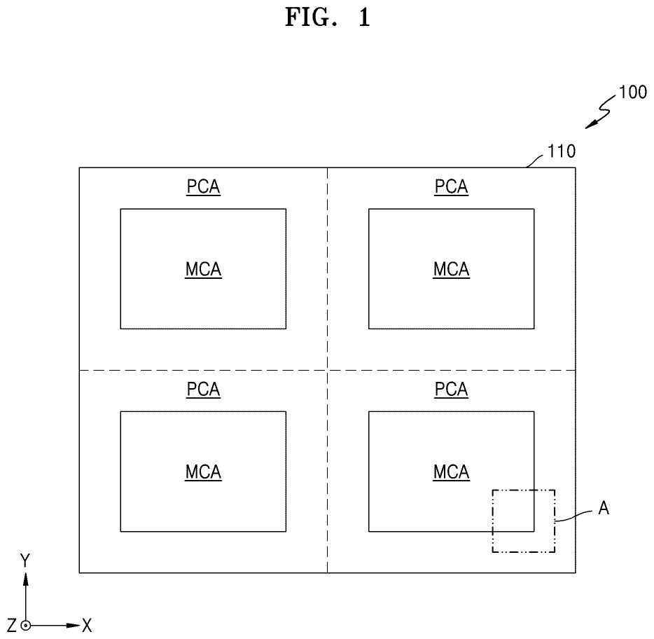

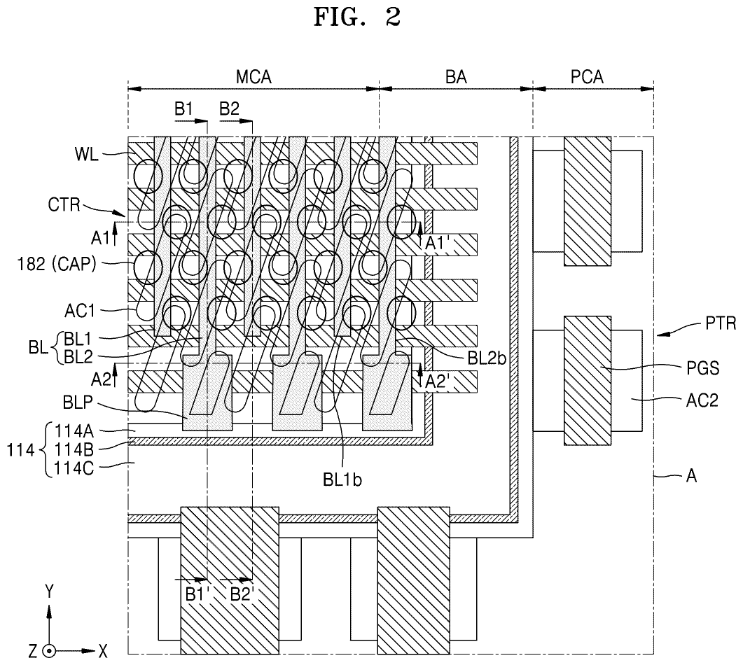

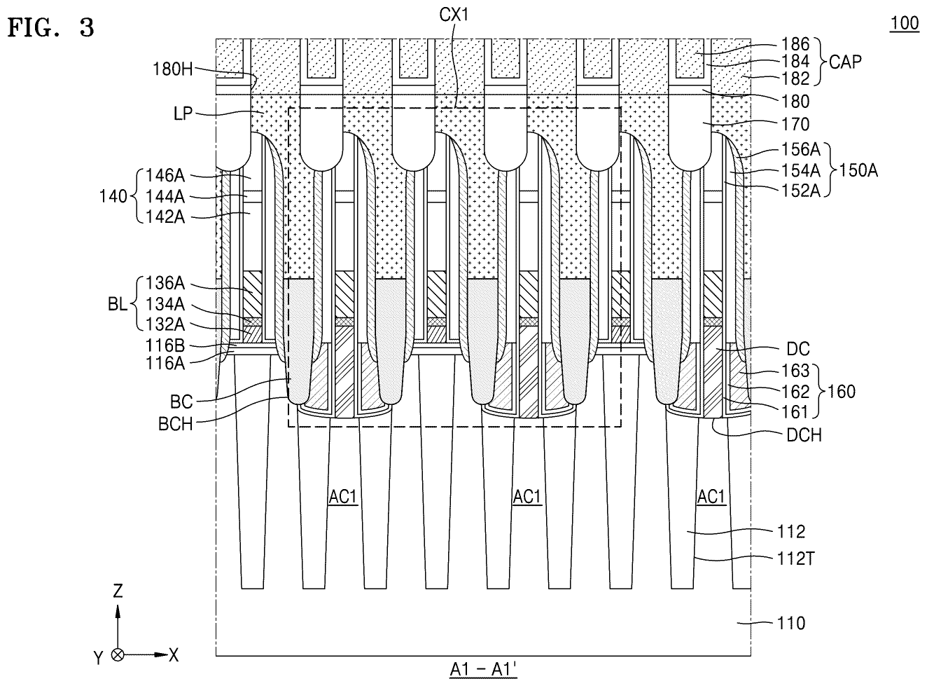

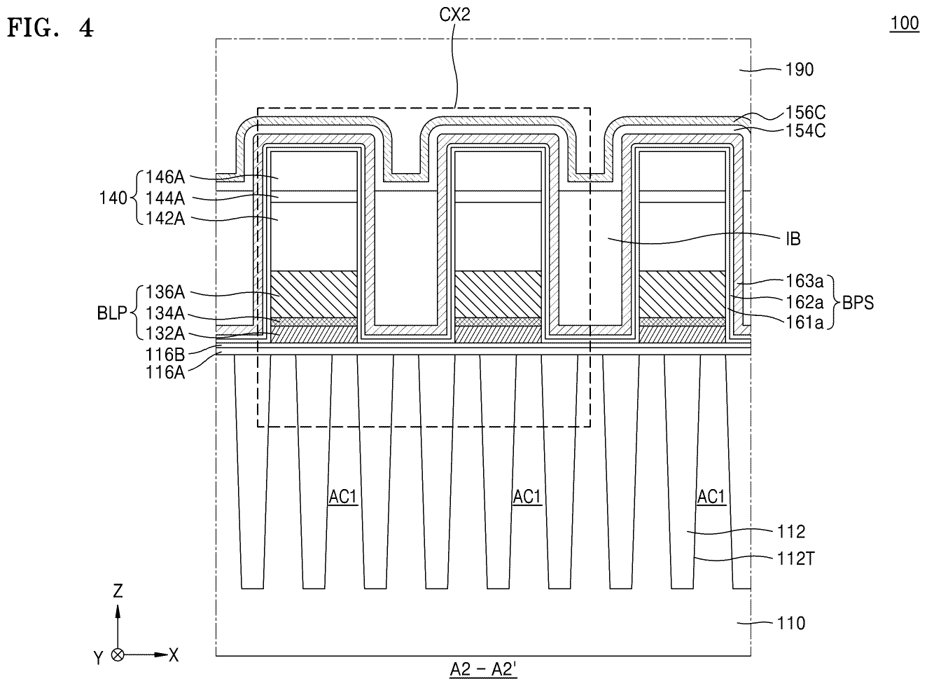

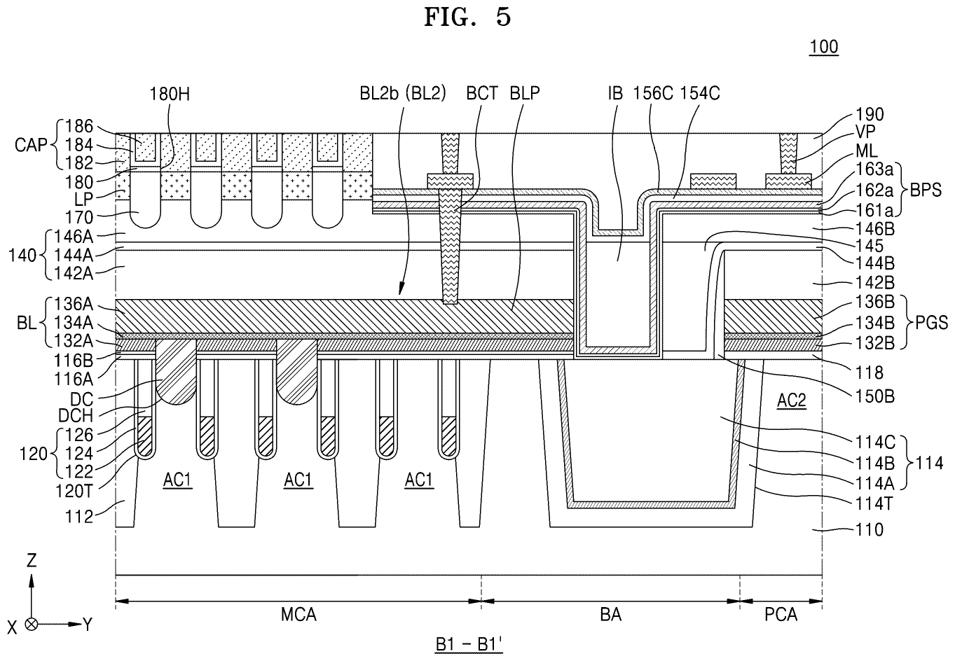

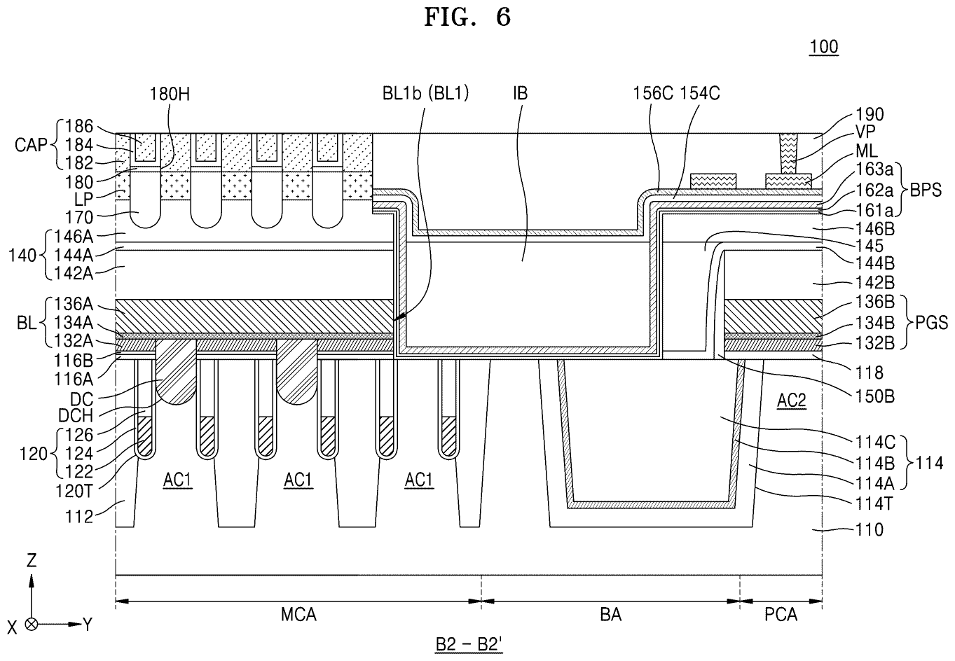

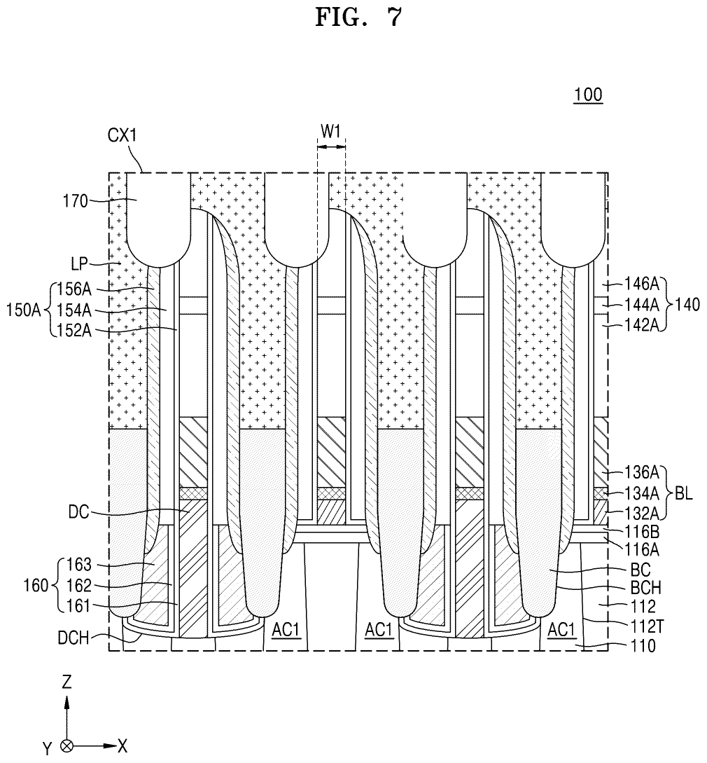

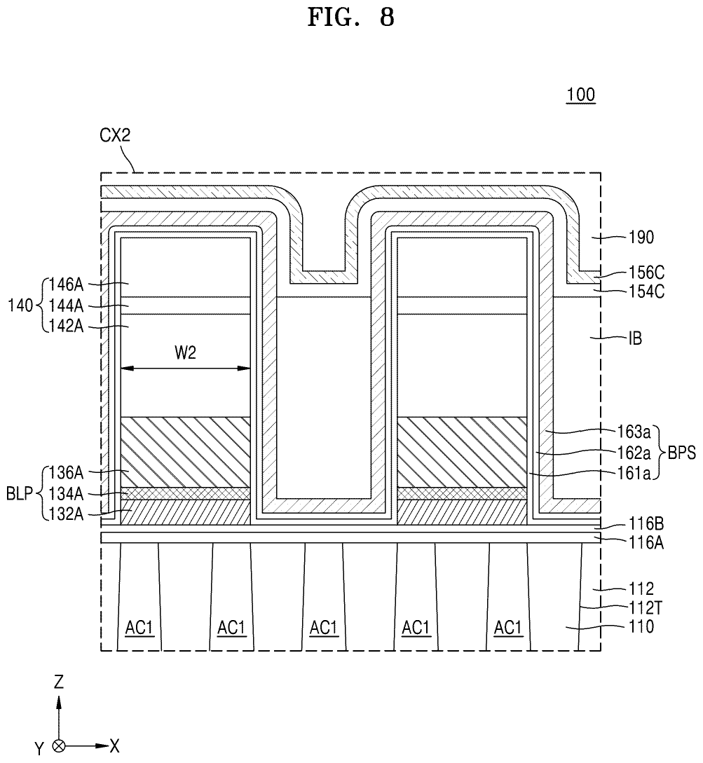

FIG. 1 is a layout diagram illustrating a semiconductor device 100 according to some embodiments. FIG. 2 is a magnified view of a portion A of FIG. 1. FIG. 3 is a cross-sectional view taken along line A1-A1′ of FIG. 2. FIG. 4 is a cross-sectional view taken along line A2-A2′ of FIG. 2. FIG. 5 is a cross-sectional view taken along line B1-B1′ of FIG. 2. FIG. 6 is a cross-sectional view taken along line B2-B2′ of FIG. 2. FIG. 7 is a magnified view of a portion CX1 of FIG. 3. FIG. 8 is a magnified view of a portion CX2 of FIG. 4.

Referring to FIGS. 1 to 8, the semiconductor device 100 may include a substrate 110 including a cell array area MCA and a peripheral circuit area PCA. The cell array area MCA may be a memory cell array of a dynamic random access memory (DRAM) device, and the peripheral circuit area PCA may be a core area or a peripheral circuit area of the DRAM device. For example, the cell array area MCA may include a cell transistor CTR and a capacitor structure CAP connected to the cell transistor CTR, and the peripheral circuit area PCA may include a peripheral circuit transistor PTR configured to provide a signal and/or power to the cell transistor CTR included in the cell array area MCA. In embodiments, the peripheral circuit transistor PTR may constitute various circuits, such as a command decoder, a control logic, an address buffer, a row decoder, a column decoder, a sense amplifier, and a data input-output circuit.

In the cell array area MCA, each of a plurality of first active areas AC1 may be arranged to have a long axis in a diagonal direction with respect to a first horizontal direction X and a second horizontal direction Y. A plurality of word lines WL may extend in the first horizontal direction X to be parallel to each other across the plurality of first active areas AC1. Above the plurality of word lines WL, a plurality of bit lines BL may extend in the second horizontal direction Y to be parallel to each other.

The plurality of bit lines BL may be connected to the plurality of first active areas AC1 via bit line contacts DC. A plurality of buried contacts BC may be between every two bit lines BL adjacent to each other among the plurality of bit lines BL. A plurality of landing pads LP may be formed on the plurality of buried contacts BC, respectively. Each of the plurality of buried contacts BC and each of the plurality of landing pads LP may electrically connect a lower electrode 182 of the capacitor structure CAP formed above each of the plurality of bit lines BL to a first active area AC1.

As shown in FIG. 2, a bit line pad BLP may be at an end portion of each of the plurality of bit lines BL. The bit line pad BLP may have a greater width in the first horizontal direction X than a bit line BL and be integrally connected to an end portion of a corresponding bit line BL. That is, the bit line pad BLP and the end portion of a corresponding bit line BL may form a monolithic structure. For example, the bit line pad BLP may collectively have a hammer shape together with the corresponding bit line BL, and for example, the bit line pad BLP may have a hammer head shape connected to a hammer handle. A bit line contact BCT may be on the bit line pad BLP.

In some embodiments, the plurality of bit lines BL may include a first bit line BL1 and a second bit line BL2 that are alternately arranged, a bit line pad BLP corresponding to the first bit line BL1 may be electrically connected to a first end portion of the first bit line BL1, and no bit line pad BLP may be at a second end portion BL1b of the first bit line BL1. A bit line pad BLP corresponding to the second bit line BL2 may be electrically connected to a second end portion BL2b of the second bit line BL2, and no bit line pad BLP may be at a first end portion of the second bit line BL2. FIG. 2 shows a magnified corner portion of the cell array area MCA, which includes the second end portion BL1b of the first bit line BL1, the second end portion BL2b of the second bit line BL2, and the bit line pad BLP electrically connected to the second end portion BL2b of the second bit line BL2.

The substrate 110 may include silicon, e.g., monocrystalline silicon, polycrystalline silicon, or amorphous silicon. In some embodiments, the substrate 110 may include at least one material selected from among germanium (Ge), silicon germanium (SiGe), silicon carbide (SiC), gallium arsenide (GaAs), indium arsenide (InAs), and/or indium phosphide (InP). In some embodiments, the substrate 110 may include a conductive area, e.g., an impurity-doped well or an impurity-doped structure.

A device isolation trench 112T may be formed in the substrate 110, and a device isolation layer 112 may be formed in the device isolation trench 112T. In the cell array area MCA, the plurality of first active areas AC1 may be defined in the substrate 110 by the device isolation layer 112, and in the peripheral circuit area PCA, a plurality of second active areas AC2 may be defined in the substrate 110 by the device isolation layer 112. The device isolation layer 112 may include an oxide film, a nitride film, or a combination thereof.

A boundary trench 114T may be formed in a boundary area BA between the cell array area MCA and the peripheral circuit area PCA, and a boundary insulating structure 114 may be formed in the boundary trench 114T. In a top view, the boundary trench 114T may surround the four sides of the cell array area MCA. The boundary insulating structure 114 may include a buried insulating layer 114A, an insulating liner 114B, and a gap-fill insulating layer 114C inside the boundary trench 114T.

The buried insulating layer 114A may be conformally formed on the inner wall of the boundary trench 114T. In embodiments, the buried insulating layer 114A may include silicon oxide. For example, the buried insulating layer 114A may include silicon oxide formed by an atomic layer deposition (ALD) process, a chemical vapor deposition (CVD) process, a plasma enhanced CVD (PECVD) process, a low pressure CVD (LPCVD) process, or the like.

The insulating liner 114B may be conformally formed on the buried insulating layer 114A on the inner wall of the boundary trench 114T. In embodiments, the insulating liner 114B may include silicon nitride. For example, the insulating liner 114B may include silicon nitride formed by an ALD process, a CVD process, a PECVD process, an LPCVD process, or the like.

The gap-fill insulating layer 114C may be on the insulating liner 114B to at least partially fill the inside of the boundary trench 114T. In some embodiments, the gap-fill insulating layer 114C may include at least one of tonen silazene (TOSZ), undoped silicate glass (USG), boro-phospho-silicate glass (BPSG), phosphosilicate glass (PSG), flowable oxide (FOX), plasma enhanced deposition of tetra-ethyl-ortho-silicate (PE-TEOS), and/or fluoride silicate glass (FSG).

In the cell array area MCA, a plurality of word line trenches 120T extending in the first horizontal direction X may be in the substrate 110 and a buried gate structure 120 may be in each of the plurality of word line trenches 120T. The buried gate structure 120 in each of the plurality of word line trenches 120T may include a gate electrode 122, a gate dielectric layer 124, and a capping insulating layer 126. A plurality of gate electrodes 122 may respectively correspond to the plurality of word lines WL shown in FIG. 2.

The plurality of gate electrodes 122 may include titanium (Ti), titanium nitride (TiN), tantalum (Ta), tantalum nitride (TaN), tungsten (W), tungsten nitride (WN), titanium silicon nitride (TiSiN), tungsten silicon nitride (WSiN), or a combination thereof. A plurality of gate dielectric layers 124 may include a silicon oxide film, a silicon nitride film, a silicon oxynitride film, an oxide/nitride/oxide (ONO) film, and/or a high-k dielectric film having a higher dielectric constant than the silicon oxide film. A plurality of capping insulating layers 126 may include a silicon oxide film, a silicon nitride film, a silicon oxynitride film, or a combination thereof.

The plurality of word line trenches 120T may extend into the boundary area BA from the cell array area MCA, and an end portion of each of the plurality of word line trenches 120T may overlap the boundary insulating structure 114 in the vertical direction Z in the boundary area BA.

In the cell array area MCA, a first buffer insulating layer 116A and a second buffer insulating layer 116B may be sequentially stacked on the substrate 110, the buried gate structure 120, and the boundary insulating structure 114. Each of the first buffer insulating layer 116A and the second buffer insulating layer 116B may include silicon oxide, silicon oxynitride, and/or silicon nitride.

A plurality of bit line contacts DC may be respectively formed in a plurality of bit line contact holes DCH in the substrate 110. The plurality of bit line contacts DC may be electrically connected to the plurality of first active areas AC1. The plurality of bit line contacts DC may include TIN, TiSiN, W, tungsten silicide, doped polysilicon, or a combination thereof.

On the plurality of bit line contacts DC, the plurality of bit lines BL may extend lengthwise in the second horizontal direction Y. Each of the plurality of bit lines BL may be electrically connected to a first active area AC1 via a bit line contact DC. In some embodiments, each of the plurality of bit lines BL may include a lower conductive pattern 132A, an intermediate conductive pattern 134A, and an upper conductive pattern 136A sequentially stacked on the substrate 110.

In some embodiments, the lower conductive pattern 132A may include any one of Si, Ge, W, WN, cobalt (Co), nickel (Ni), aluminum (A1), molybdenum (Mo), ruthenium (Ru), Ti, TiN, Ta, TaN, copper (Cu), cobalt silicide, nickel silicide, and/or tungsten silicide. In some embodiments, the intermediate conductive pattern 134A may include TiN, TiSiN, or a combination thereof, and the upper conductive pattern 136A may include any one of W, Ru, Mo, Co, Ti, rhodium (Ro), iridium (Ir), and/or an alloy thereof.

The plurality of bit lines BL may be at least partially covered by a plurality of insulating capping structures 140, respectively. The plurality of insulating capping structures 140 may extend in the second horizontal direction Y on the plurality of bit lines BL, respectively. Each of the plurality of insulating capping structures 140 may include a lower capping pattern 142A, a capping liner 144A, and an upper capping pattern 146A. The lower capping pattern 142A, the capping liner 144A, and the upper capping pattern 146A may include silicon nitride and/or silicon oxynitride.

A bit line spacer 150A may be on both sidewalls of each of the plurality of bit lines BL and on both sidewalls of each of the plurality of insulating capping structures 140. The bit line spacer 150A may extend in the second horizontal direction Y on both sidewalls of each of the plurality of bit lines BL.

In some embodiments, the bit line spacer 150A may include a first spacer layer 152A, a second spacer layer 154A, and a third spacer layer 156A sequentially stacked on a sidewall of a bit line BL. In embodiments, the first spacer layer 152A may include silicon nitride and/or silicon oxynitride, the second spacer layer 154A may include silicon oxide, and the third spacer layer 156A may include silicon nitride and/or silicon oxynitride.

A bit line contact spacer 160 may be on the inner wall of a bit line contact hole DCH. The bit line contact spacer 160 may be on a lower sidewall of the bit line contact hole DCH and at least partially cover a lower side of a bit line contact DC. The bit line contact spacer 160 may include a first liner 161, a second liner 162, and a third liner 163. The first liner 161, the second liner 162, and the third liner 163 may be sequentially stacked on the inner wall of the bit line contact hole DCH. In embodiments, the first liner 161 may include silicon nitride and/or silicon oxynitride, the second liner 162 may include silicon oxide, and the third liner 163 may include silicon nitride and/or silicon oxynitride.

In some embodiments, the first spacer layer 152A of the bit line spacer 150A may be simultaneously formed in a process of forming the first liner 161 of the bit line contact spacer 160 and may be integrally connected to the first liner 161 of the bit line contact spacer 160. That is, the first spacer layer 152A and the first liner 161 may form a monolithic structure.

The plurality of buried contacts BC may be between the plurality of bit lines BL, respectively. For example, an upper side of each of the plurality of buried contacts BC may be between two adjacent bit line spacers 150A and in contact with the two adjacent bit line spacers 150A, e.g., at least partially surrounded by two adjacent third spacer layers 156A. A lower side of each of the plurality of buried contacts BC may be inside a buried contact hole BCH extending into the substrate 110 and in contact with the bit line contact spacer 160. A bottom portion and a sidewall lower side of each of the plurality of buried contacts BC may be in contact with a first active area AC1. In embodiments, the plurality of buried contacts BC may include doped polysilicon.

A plurality of insulating fences (not shown) may extend in the second horizontal direction Y between every two adjacent bit lines BL. The plurality of insulating fences may be at positions vertically (Z direction) overlapping the plurality of word line trenches 120T, respectively. In a top plan view, the plurality of buried contacts BC and the plurality of insulating fences may be alternately arranged between every two bit lines BL extending in the second horizontal direction Y.

The plurality of landing pads LP may be on the plurality of buried contacts BC, respectively. Each of the plurality of landing pads LP may include a conductive barrier layer (not shown) and a landing pad conductive layer (not shown). The conductive barrier layer may include Ti, TiN, or a combination thereof. The landing pad conductive layer may include a metal, metal nitride, conductive polysilicon, or a combination thereof. For example, the landing pad conductive layer may include W. The plurality of landing pads LP may have a plurality of island pattern shapes in a top plan view, respectively.

The plurality of landing pads LP may be electrically isolated from each other by an insulating pattern 170 at least partially surrounding the perimeters of the plurality of landing pads LP. The insulating pattern 170 may include at least one of silicon nitride, silicon oxide, and/or silicon oxynitride.

An etching stop layer 180 may be on the insulating pattern 170 and have an opening 180H. The opening 180H may be at a position corresponding to a landing pad LP, and the upper surface of the landing pad LP may be coplanar with the bottom of the opening 180H.

The capacitor structure CAP may be on the etching stop layer 180. The capacitor structure CAP may include the lower electrode 182, a capacitor dielectric layer 184, and an upper electrode 186. A bottom portion of the lower electrode 182 may be disposed in the opening 180H of the etching stop layer 180 such that the bottom portion of the lower electrode 182 is on the landing pad LP. The capacitor dielectric layer 184 may conformally cover the lower electrode 182 with a relatively small thickness, and the upper electrode 186 may be on the capacitor dielectric layer 184.

The bit line pad BLP may be at an end portion of each of the plurality of bit lines BL. In some embodiments, the bit line pad BLP may be in the cell array area MCA adjacent to the boundary area BA. In some embodiments, a portion of the bit line pad BLP may be in the cell array area MCA adjacent to the boundary area BA, and the other portion of the bit line pad BLP may be in the boundary area BA. In some embodiments, the entire bit line pad BLP may be in the boundary area BA.

The bit line pad BLP may be integrally connected to each of the plurality of bit lines BL. As described above, in the plan layout diagram shown in FIG. 2, a first bit line BL1 may be between two adjacent second bit lines BL2 and two bit line pads BLP connected to the two adjacent second bit lines BL2 may be adjacent to each other in the first horizontal direction X.

In embodiments, the bit line pad BLP may be an end portion region patterned to have a greater width than each of the plurality of bit lines BL in a process of patterning the plurality of bit lines BL. Accordingly, the bit line pad BLP may have the same stack structure as the bit line BL. For example, the bit line pad BLP may have the same material configuration as the lower conductive pattern 132A, the intermediate conductive pattern 134A, and the upper conductive pattern 136A of the bit line BL. An insulating capping structure 140 on the bit line pad BLP may also be patterned to have the same width as the bit line pad BLP, and the sidewalls of the bit line pad BLP may be aligned and consecutively connected to the sidewalls of the insulating capping structure 140.

In some embodiments, each of the plurality of bit lines BL may have a first width W1 (see FIG. 7) in the first horizontal direction X and each of a plurality of bit line pads BLP may have a second width W2 (see FIG. 8) that is greater than the first width W1 in the first horizontal direction X. In some embodiments, when the plurality of bit lines BL are arranged at a first pitch, the plurality of bit line pads BLP may be arranged at a second pitch that is about twice the first pitch.

A boundary spacer BPS may be on the sidewalls and the upper surface of the bit line pad BLP, and an insulating block IB may be on a sidewall of the boundary spacer BPS. The insulating block IB may be between two adjacent bit line pads BLP. In some embodiments, the insulating block IB may be between the bit line pad BLP and a peripheral circuit gate electrode PGS in the boundary area BA. In some embodiments, as shown in FIG. 6, the boundary spacer BPS may be further disposed between an end portion of a bit line BL (e.g., an end portion of a bit line BL not connected to a bit line pad BLP or the second end portion BL1b of the first bit line BL1 shown in FIG. 2) and the insulating block IB.

In some embodiments, the boundary spacer BPS may include a first liner 161a, a second liner 162a, and a third liner 163a. The first liner 161a, the second liner 162a, and the third liner 163a of the boundary spacer BPS may be formed in the same process as the first liner 161, the second liner 162, and the third liner 163 of the bit line contact spacer 160, respectively. For example, the first liner 161a, the second liner 162a, and the third liner 163a of the boundary spacer BPS may be formed to include the same materials as those of the first liner 161, the second liner 162, and the third liner 163 of the bit line contact spacer 160, respectively.

In embodiments, the first liner 161a may include silicon nitride and/or silicon oxynitride, the second liner 162a may include silicon oxide, and the third liner 163a may include silicon nitride and/or silicon oxynitride.

In embodiments, the insulating block IB may include silicon oxide. In embodiments, the insulating block IB may include at least one of TOSZ, USG, BPSG, PSG, FOX, PE-TEOS, and/or FSG.

In some embodiments, an interface layer formed with a relatively small thickness may be further provided between the insulating block IB and a sidewall of the boundary spacer BPS and may include silicon oxide formed by an ALD or CVD process.

In some embodiments, the insulating block IB may have an upper surface at a lower level in the vertical direction (Z direction) than the upper surface of the insulating capping structure 140 on the bit line pad BLP. In some embodiments, the insulating block IB may have an upper surface at a higher level in the vertical direction (Z direction) than the upper surface of the bit line pad BLP.

In some embodiments, the insulating block IB may at least partially surround an end portion of the bit line BL while at least partially filling the space between two adjacent bit line pads BLP. For example, a portion of the insulating block IB may be in the space between the second end portion BL1b of the first bit line BL1 and the second bit line BL2, and as shown in FIG. 6, in contact with the boundary spacer BPS on the second end portion BL1b of the first bit line BL1.

A first insulating capping layer 154C and a second insulating capping layer 156C may be further provided on the upper surface of the boundary spacer BPS on the upper surface of the bit line pad BLP, and on the upper surface of the insulating block IB. The bit line contact BCT may be on the bit line pad BLP. The bit line contact BCT may be electrically connected to the bit line pad BLP by penetrating or extending through the insulating capping structure 140 on the bit line pad BLP.

In the peripheral circuit area PCA, the peripheral circuit transistor PTR may be in a second active area AC2. The peripheral circuit transistor PTR may include a gate dielectric layer 118, the peripheral circuit gate electrode PGS, and a gate capping pattern 142B sequentially stacked in the second active area AC2.

The gate dielectric layer 118 may include at least one material selected from among a silicon oxide film, a silicon nitride film, a silicon oxynitride film, an ONO film, and/or a high-k dielectric film having a higher dielectric constant than the silicon oxide film. The gate capping pattern 142B may include silicon nitride or silicon oxynitride.

The peripheral circuit gate electrode PGS may include a second conductive layer 132B, a second intermediate layer 134B, and a second metal layer 136B. In some embodiments, the second conductive layer 132B may include Si, Ge, W, WN, Co, Ni, A1, Mo, Ru, Ti, TiN, Ta, TaN, Cu, or a combination thereof. The second intermediate layer 134B may include TiN, TiSiN, or a combination thereof, and the second metal layer 136B may include any one of W, Ru, Mo, Co, Ti, Ro, Ir, and/or an alloy thereof.

Both sidewalls of the peripheral circuit gate electrode PGS and the gate capping pattern 142B may be at least partially covered by an insulating spacer 150B. The insulating spacer 150B may include an oxide film, a nitride film, or a combination thereof. The peripheral circuit transistor PTR and the insulating spacer 150B may be at least partially covered by a protective layer 144B, and a first interlayer insulating layer 145 may be on a sidewall of the protective layer 144B to at least partially fill the space between two adjacent peripheral circuit transistors PTR. A capping insulating layer 146B may be on the protective layer 144B and the first interlayer insulating layer 145.

In some embodiments, at least a portion of the boundary spacer BPS may be selectively on the capping insulating layer 146B. The boundary spacer BPS may be between the insulating block IB and the boundary insulating structure 114 in the boundary area BA and extend on the capping insulating layer 146B. In some embodiments, the first insulating capping layer 154C and the second insulating capping layer 156C may be further disposed on the upper surface of the boundary spacer BPS.

In the peripheral circuit area PCA, a wiring line ML and a via plug VP may be on the first interlayer insulating layer 145 and the capping insulating layer 146B (or selectively on the boundary spacer BPS or the second insulating capping layer 156C) and a second interlayer insulating layer 190 may at least partially surround the wiring line ML and the via plug VP.

In general, as the line width of each of a plurality of bit lines decreases and the gap between two adjacent bit lines decreases, the difficulty of a process of forming a buried contact hole increases. In particular, in a process of patterning a bit line with a fine line width by using a lithography process, such as extreme ultraviolet (EUV), a bit line pad integrally connected to the bit line and having a relatively large width is formed. However, because the width between bit line pads (e.g., bit line pads connected to second bit lines) is relatively large, local erosion or removal of a spacer layer may occur on a side wall of a bit line (e.g., the second end portion BL2b of the first bit line BL1) in an etching process of forming a buried contact hole, and a metal material constituting the bit line may also be removed in a subsequent wet etching process by the local erosion of the spacer layer, thereby forming a void.

However, according to the embodiments described above, the boundary spacer BPS and the insulating block IB may be in the space between adjacent bit line pads BLP, and an end portion of the bit line BL (e.g., the second end portion BL2b of the first bit line BL1) may be at least partially covered by the insulating block IB so as not to be exposed in an etching process of forming the buried contact hole BCH. Therefore, a void defect that the bit line BL is removed by local erosion of the bit line spacer 150A may be prevented.

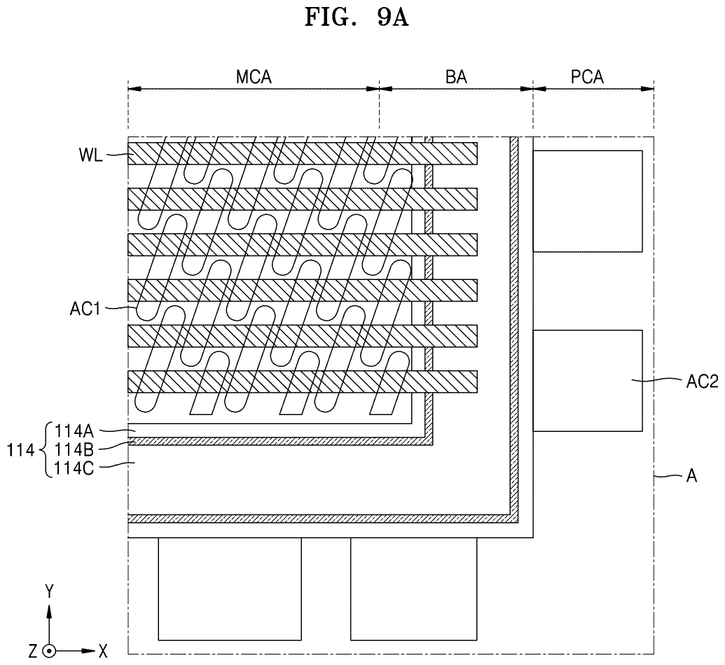

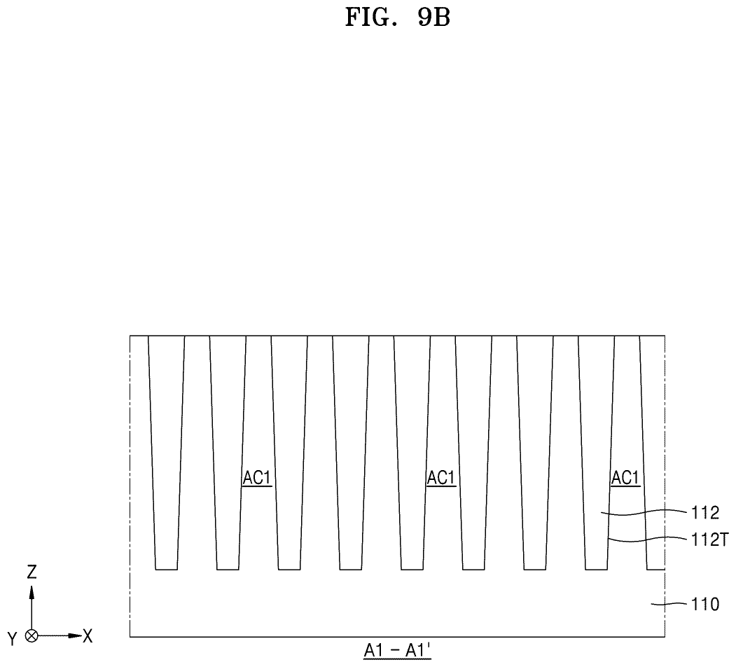

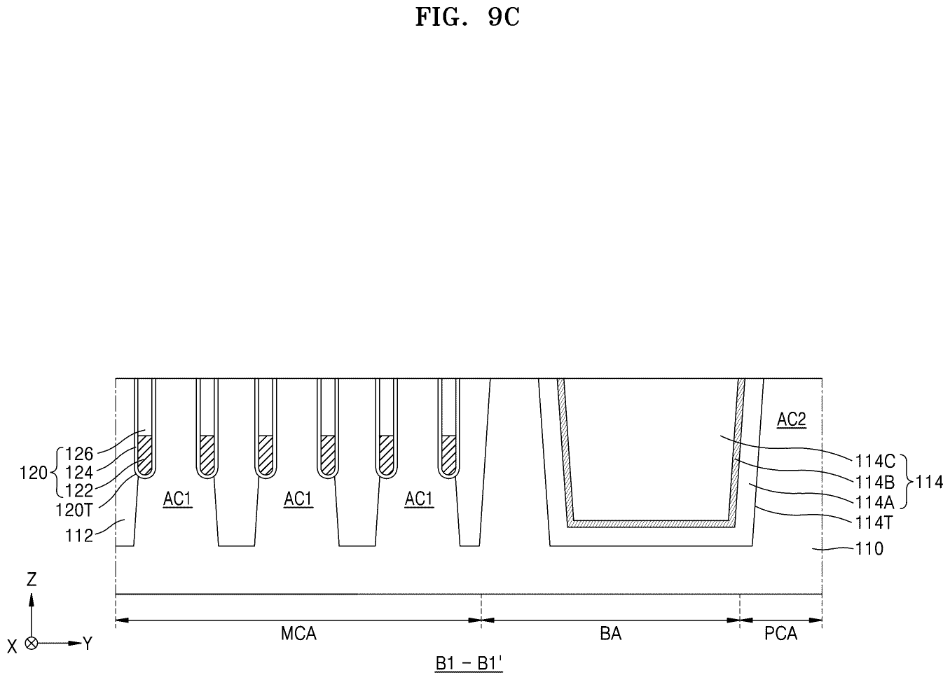

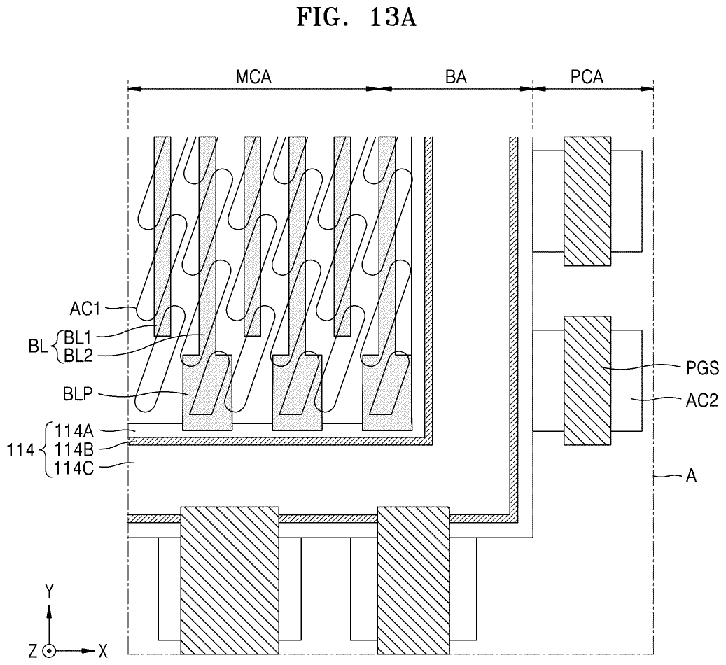

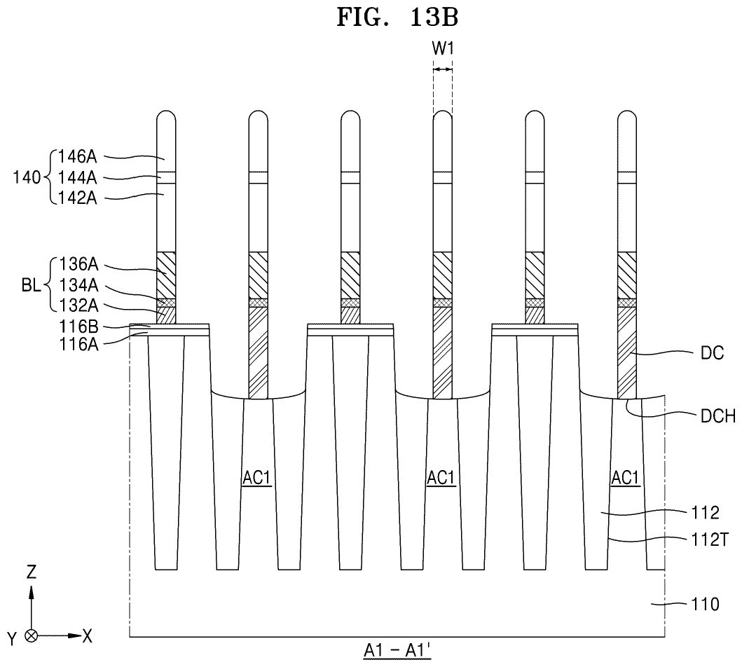

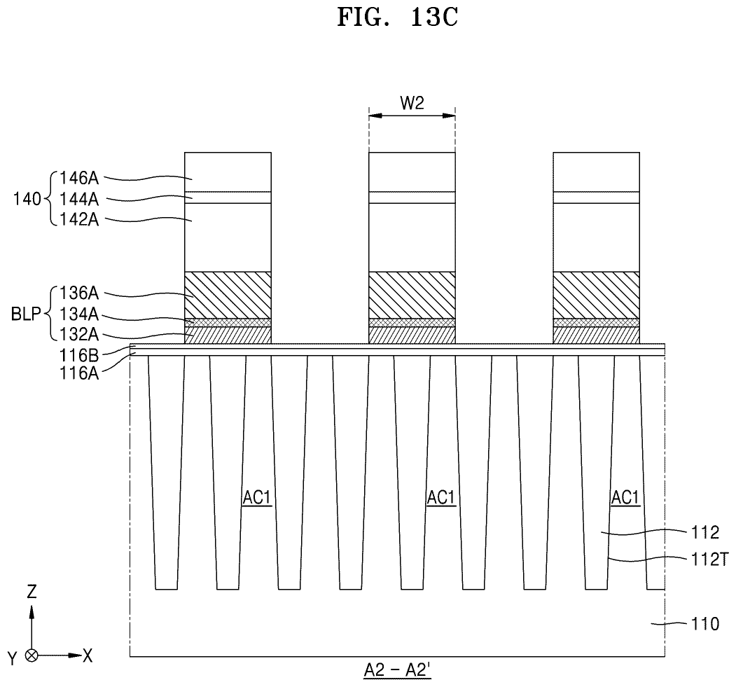

FIGS. 9A, 9B, 9C, 10A, 10B, 11A, 11B, 12, 13A, 13B, 13C, 14A, 14B, 15A, 15B, 16A, 16B, 16C, 17A, 17B, 17C, 18, 19A, 19B, 20A, 20B, 20C, 21A, and 21B are top plan views and cross-sectional views illustrating a method of manufacturing a semiconductor device 100, according to some embodiments. Particularly, FIGS. 9B, 10A, 11A, 13B, 14A, 15A, 16B, 17B, 18, 19A, 20A, and 21A are cross-sectional views taken along line A1-A1′ of FIG. 2, FIGS. 13C, 14B, 15B, 16C, 17C, 19B, 20B, and 21B are cross-sectional views taken along line A2-A2′ of FIG. 2, FIGS. 9C, 10B, 11B, 12, and 20C are cross-sectional views taken along line B1-B1′ of FIG. 2, and FIGS. 9A, 13A, 16A, and 17A are top plan views corresponding to operations of FIGS. 9B, 13B, 16B, and 17B.

Referring to FIGS. 9A to 9C, a portion of the substrate 110 may be removed to form a plurality of device isolation trenches 112T in the cell array area MCA and the peripheral circuit area PCA of the substrate 110 and form the boundary trench 114T in the boundary area BA of the substrate 110.

Thereafter, the device isolation layer 112 at least partially filling the plurality of device isolation trenches 112T may be formed in the cell array area MCA and the peripheral circuit area PCA. By forming the device isolation layer 112, the plurality of first active areas AC1 are defined in the cell array area MCA and the second active area AC2 is defined in the peripheral circuit area PCA.

In some embodiments, the device isolation layer 112 may be formed using silicon oxide, silicon nitride, silicon oxynitride, or a combination thereof. In some embodiments, the device isolation layer 112 may be formed by a dual-layer structure of a silicon oxide layer and a silicon nitride layer but embodiments are not limited thereto.

Thereafter, the buried insulating layer 114A, the insulating liner 114B, and the gap-fill insulating layer 114C may be sequentially formed on the inner wall of the boundary trench 114T, and the boundary insulating structure 114 may be formed by planarizing upper portions of the buried insulating layer 114A, the insulating liner 114B, and the gap-fill insulating layer 114C so that the upper surface of the substrate 110 is at least partially exposed.

In some embodiments, the buried insulating layer 114A may be formed using an ALD process, a CVD process, a PECVD process, an LPCVD process, or the like. In some embodiments, a process of forming the buried insulating layer 114A may be performed in the same operations as at least some operations of a process of forming the device isolation layer 112 but embodiments are not limited thereto. In some embodiments, the process of forming the buried insulating layer 114A may be separately performed after the process of forming the device isolation layer 112.

In some embodiments, the insulating liner 114B may be formed using silicon nitride by an ALD process, a CVD process, a PECVD process, an LPCVD process, or the like. The gap-fill insulating layer 114C may be formed on the insulating liner 114B to at least partially fill the inside of the boundary trench 114T. The gap-fill insulating layer 114C may be formed with a large thickness enough to substantially fill the remaining portion of the inside of the boundary trench 114T.

In some embodiments, the gap-fill insulating layer 114C may include silicon oxide, such as TOSZ, USG, BPSG, PSG, FOX, PE-TEOS, and/or FSG.

Thereafter, a mask pattern (not shown) may be formed on the substrate 110, and the mask pattern may be used as an etching mask to remove a portion of the cell array area MCA of the substrate 110, thereby forming a word line trench 120T. The word line trench 120T may extend from the cell array area MCA to a portion of the boundary area BA.

Thereafter, the gate dielectric layer 124, the gate electrode 122, and the capping insulating layer 126 may be sequentially formed inside the word line trench 120T.

For example, the gate dielectric layer 124 may be conformally formed on the inner wall of the word line trench 120T. The gate electrode 122 may be formed by at least partially filling the word line trench 120T with a conductive layer (not shown) and then etching back an upper portion of the conductive layer to at least partially expose a portion of an upper side of the word line trench 120T again. The capping insulating layer 126 may be formed by substantially filling the remaining portion of the word line trench 120T with an insulating material and planarizing the insulating material so that the upper surface of the buried insulating layer 114A is at least partially exposed.

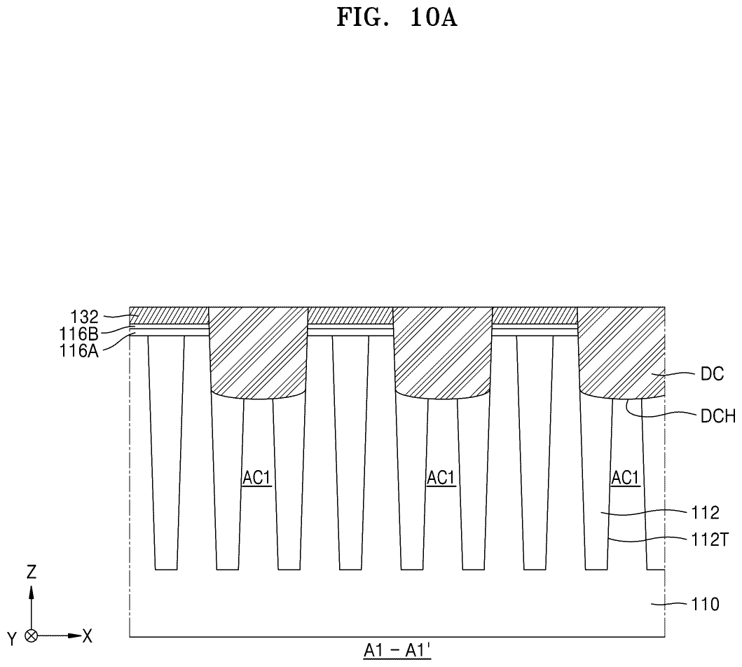

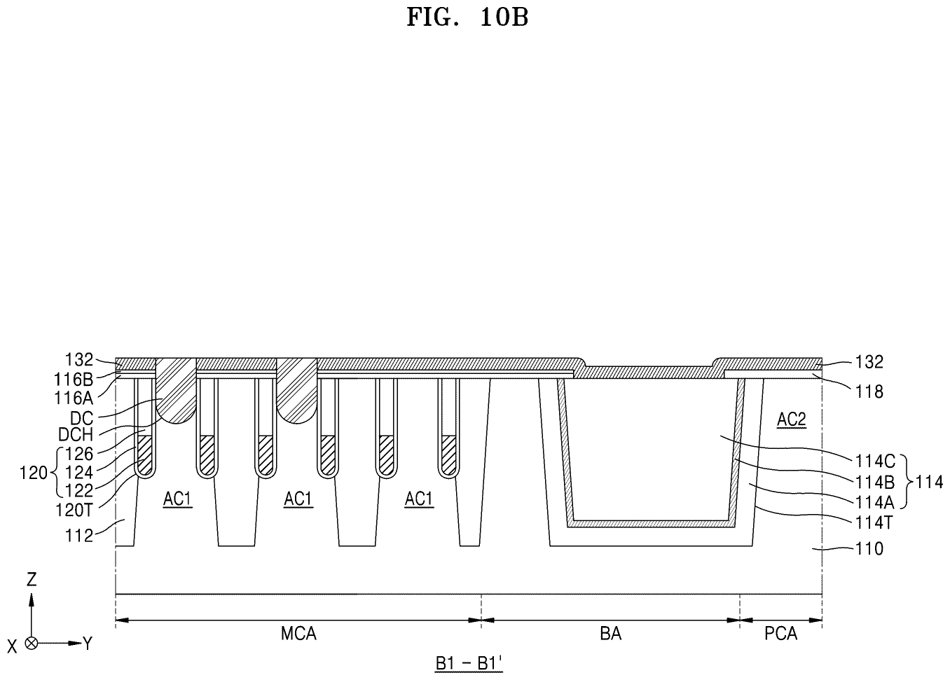

Referring to FIGS. 10A and 10B, the first buffer insulating layer 116A and the second buffer insulating layer 116B may be formed in the cell array area MCA and the boundary area BA.

In embodiments, the first buffer insulating layer 116A may be formed using silicon oxide and the second buffer insulating layer 116B may be formed using silicon nitride.

The first buffer insulating layer 116A and the second buffer insulating layer 116B may at least partially cover the upper surface of the first active area AC1 in the cell array area MCA, and in the peripheral circuit area PCA, the upper surface of the second active area AC2 may not be covered by the first buffer insulating layer 116A and the second buffer insulating layer 116B, i.e., the upper surface of the second active area AC2 may be substantially free of the first buffer insulating layer 116A and the second buffer insulating layer 116B.

Thereafter, the gate dielectric layer 118 may be formed on the substrate 110 in the peripheral circuit area PCA. The gate dielectric layer 118 may be formed by a thermal oxidation process, an ALD process, a CVD process, a PECVD process, an LPCVD process, or the like.

Thereafter, a lower conductive layer 132 may be formed on the first and second buffer insulating layers 116A and 116B and the gate dielectric layer 118.

In some embodiments, the lower conductive layer 132 may be formed using at least any one of Si, Ge, W, WN, Co, Ni, A1, Mo, Ru, Ti, TiN, Ta, TaN, Cu, cobalt silicide, nickel silicide, and/or tungsten silicide.

Thereafter, the bit line contact hole DCH may be formed by removing portions of the first and second buffer insulating layers 116A and 116B, the substrate 110, and the lower conductive layer 132. Thereafter, the bit line contact DC may be formed inside the bit line contact hole DCH by using a conductive material.

In some embodiments, the bit line contact DC may be formed using Si, Ge, W, WN, Co, Ni, A1, Mo, Ru, Ti, TiN, Ta, TaN, Cu, or a combination thereof.

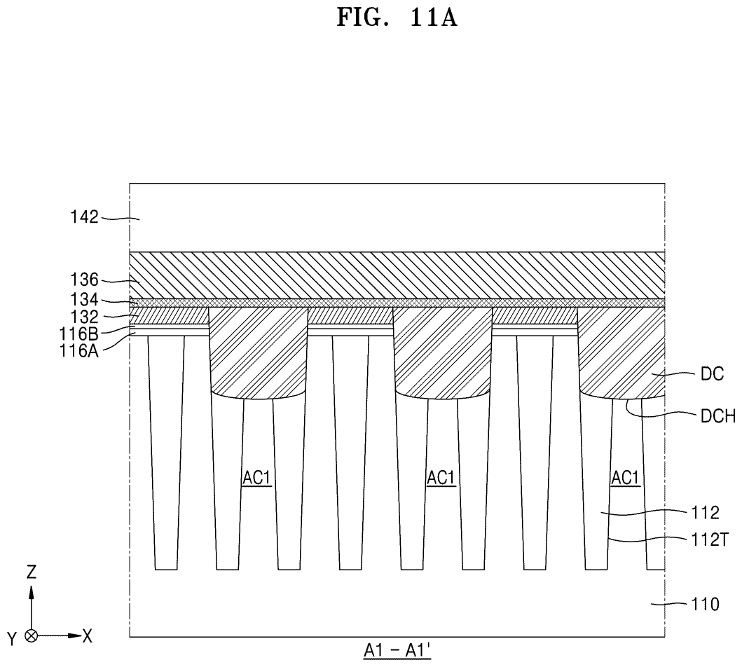

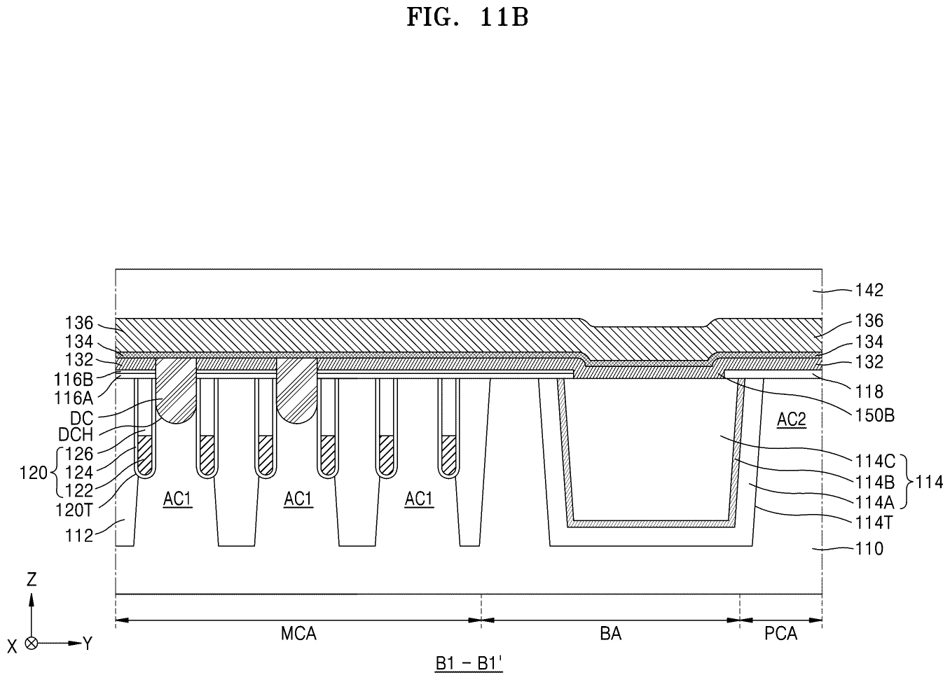

Referring to FIGS. 11A and 11B, an intermediate conductive layer 134, an upper conductive layer 136, and a capping insulating layer 142 may be sequentially formed on the lower conductive layer 132.

In some embodiments, the intermediate conductive layer 134 may be formed using TiN, TiSiN, or a combination thereof. In some embodiments, the upper conductive layer 136 may be formed using any one of W, Ru, Mo, Ti, Ro, Ir, or an alloy thereof.

In some embodiments, the intermediate conductive layer 134 and the upper conductive layer 136 may be formed using at least one of a physical vapor deposition (PVD) process, a CVD process, and an ALD process. The capping insulating layer 142 may be formed using silicon nitride or silicon oxynitride.

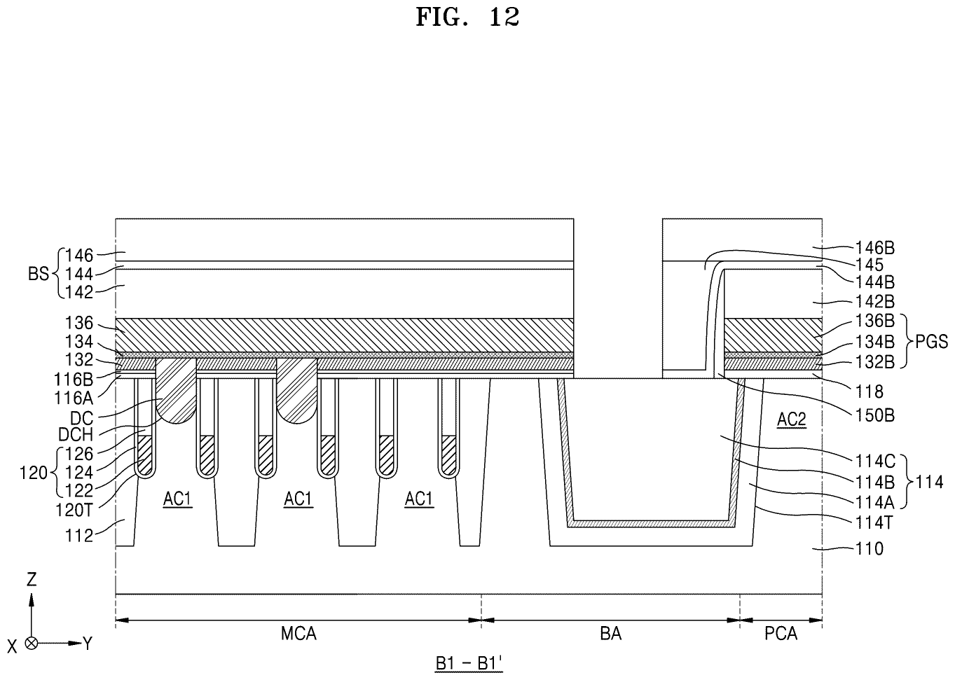

Referring to FIG. 12, in the peripheral circuit area PCA, a mask pattern may be formed on the capping insulating layer 142, and the capping insulating layer 142, the upper conductive layer 136, the intermediate conductive layer 134, and the lower conductive layer 132 may be sequentially patterned to form the peripheral circuit gate electrode PGS and the gate capping pattern 142B.

Thereafter, a gate spacer 150B may be formed on a sidewall of the peripheral circuit gate electrode PGS.

Thereafter, in the cell array area MCA, an intermediate capping layer 144 may be formed on the capping insulating layer 142, and in the peripheral circuit area PCA, the protective layer 144B may be formed on the gate spacer 150B. Thereafter, in the peripheral circuit area PCA, the first interlayer insulating layer 145 may be formed on the protective layer 144B and the capping insulating layer 146B may be formed on the first interlayer insulating layer 145. In the cell array area MCA, an upper capping layer 146 may be formed on the intermediate capping layer 144. In some embodiments, the intermediate capping layer 144 may be formed in the same process as the protective layer 144B and the capping insulating layer 146B may be formed in the same process as the upper capping layer 146, but the embodiments are not limited thereto. Herein, the capping insulating layer 142, the intermediate capping layer 144, and the upper capping layer 146 in the cell array area MCA may be referred to as a bit line capping layer stack BS.

Referring to FIGS. 13A to 13C, a mask pattern (not shown) may be formed on the bit line capping layer stack BS (see FIG. 12) and the bit line capping layer stack BS may be patterned to form the insulating capping structure 140 including the upper capping pattern 146A, the capping liner 144A, and the lower capping pattern 142A. Thereafter, the insulating capping structure 140 may be used as an etching mask to pattern the upper conductive layer 136, the intermediate conductive layer 134, and the lower conductive layer 132, thereby forming the plurality of bit lines BL.

In a patterning process of forming the plurality of bit lines BL, a portion of the bit line contact DC in the bit line contact hole DCH may also be removed. Accordingly, as shown in FIG. 13B, the sidewalls of the bit line contact DC may be aligned with the sidewalls of the bit line BL and the inner wall (e.g., the surface of the substrate 110) of the bit line contact hole DCH may be at least partially exposed at both sides of the bit line contact DC.

In some embodiments, the plurality of bit lines BL may be formed by an EUV lithography patterning process. In some embodiments, in a process of patterning the plurality of bit lines BL, the bit line pad BLP may also be patterned, such that the bit line pad BLP is integrally formed at one end of each of the plurality of bit lines BL. That is, the bit line pad BLP and the end of each of the plurality of bit lines BL may form a monolithic structure.

In embodiments, each of the plurality of bit lines BL may have the first width W1 in the first horizontal direction X and each of the plurality of bit line pads BLP may have the second width W2 that is greater than the first width W1 in the first horizontal direction X. In some embodiments, when the plurality of bit lines BL are arranged at the first pitch, the plurality of bit line pads BLP may be arranged at the second pitch that is about twice the first pitch.

In some embodiments, the bit line pad BLP may be electrically connected to one end portion of the bit line BL. The plurality of bit lines BL may include the first bit line BL1 and the second bit line BL2 that are alternately arranged, a first bit line pad connected to the first bit line BL1 may be connected to a first end portion of the first bit line BL1, and a second bit line pad connected to the second bit line BL2 may be connected to the second end portion BL2b (see FIG. 2) of the second bit line BL2. The second bit line pad may be opposite to the first bit line pad, and for example, the first bit line pad may be at a first side of the cell array area MCA and the second bit line pad may be at a second side that is opposite to the first side of the cell array area MCA.

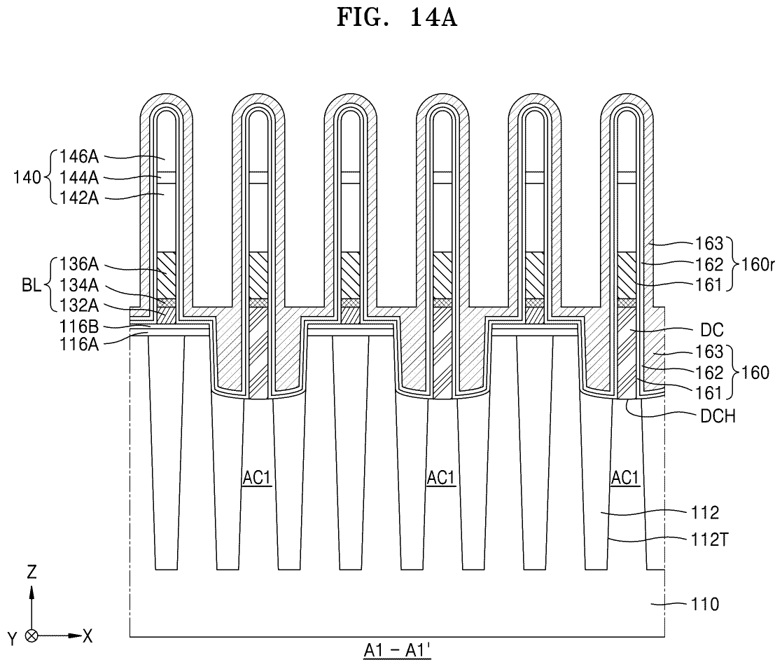

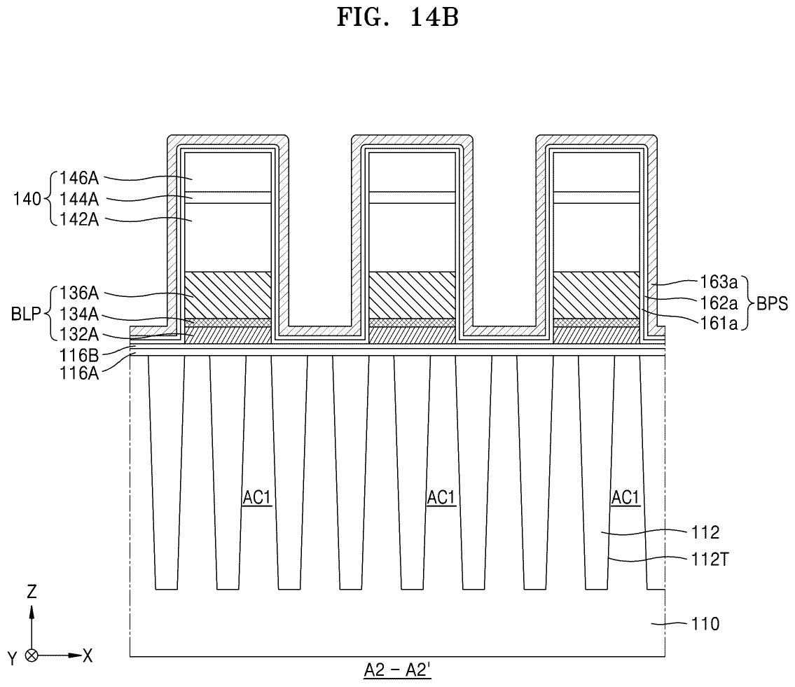

Referring to FIGS. 14A and 14B, the first liner 161, the second liner 162, and the third liner 163 may be sequentially formed on the sidewalls of the bit line BL, the insulating capping structure 140, and the bit line contact DC. The third liner 163 may be formed with a thickness large enough to substantially fill the inside of the bit line contact hole DCH.

The first liner 161, the second liner 162, and the third liner 163 may be formed together on the sidewalls and the upper surface of the bit line pad BLP and on the upper surface of the boundary insulating structure 114. In addition, the first liner 161, the second liner 162, and the third liner 163 may also be formed together on the capping insulating layer 146B in the peripheral circuit area PCA.

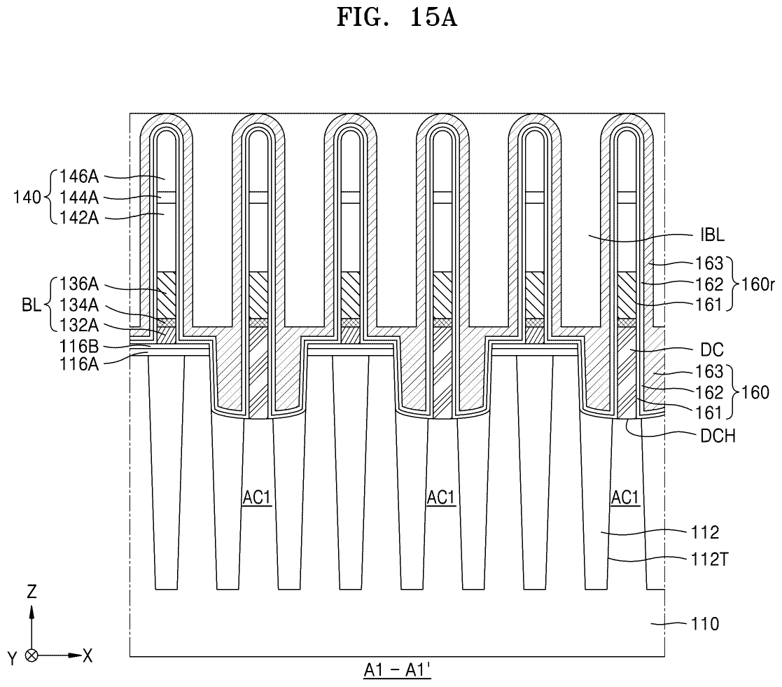

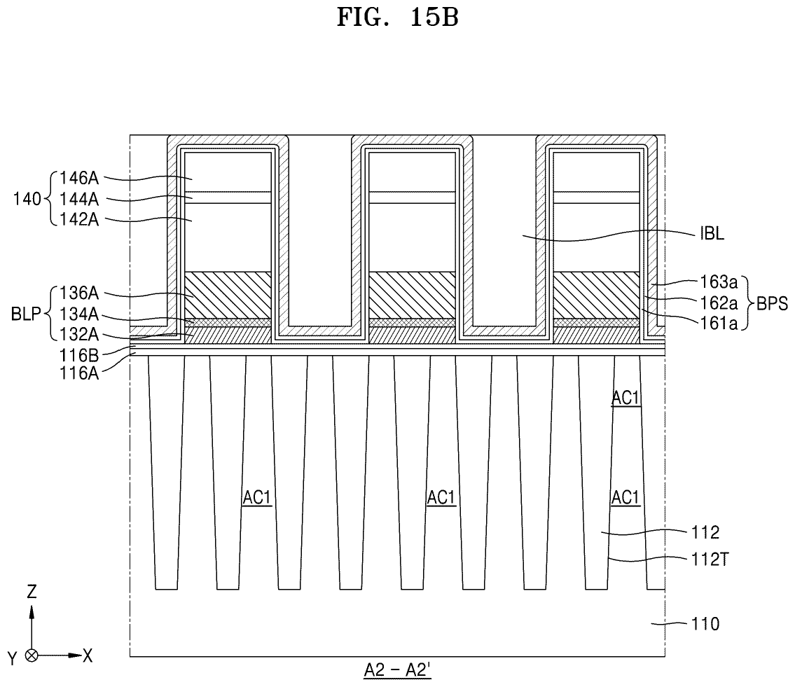

Herein, a portion corresponding to the first liner 161, the second liner 162, and the third liner 163 stacked sequentially on the inner wall of the bit line contact hole DCH may be referred to as the bit line contact spacer 160. In addition, a portion corresponding to the first liner 161, the second liner 162, and the third liner 163 on the upper surface of the insulating capping structure 140 and the sidewalls of the bit line BL and the insulating capping structure 140 may be referred to as a liner structure 160r (see FIG. 15A).

Referring to FIGS. 15A and 15B, a buried insulating layer IBL may be formed on the third liner 163. The buried insulating layer IBL may at least partially fill the space between two adjacent bit lines BL and between two adjacent insulating capping structures 140, and the buried insulating layer IBL may be between the bit line pad BLP and the peripheral circuit gate electrode PGS on the boundary insulating structure 114.

In some embodiments, the buried insulating layer IBL may include at least one of TOSZ, USG, BPSG, PSG, FOX, PE-TEOS, and/or FSG. In some embodiments, the buried insulating layer IBL may be formed using a spin coating process but embodiments are not limited thereto. In some embodiments, after forming the buried insulating layer IBL, a recess process or a chemical mechanical polishing (CMP) process of removing a portion of an upper side of the buried insulating layer IBL so that the upper surface of the third liner 163 is exposed may be further performed.

In some embodiments, before forming the buried insulating layer IBL, an interface layer may be further formed using silicon oxide by an ALD or CVD process. The interface layer may be formed with a relatively small thickness and may help the buried insulating layer IBL to be sufficiently buried without a void in a relatively narrow space between two adjacent bit lines BL.

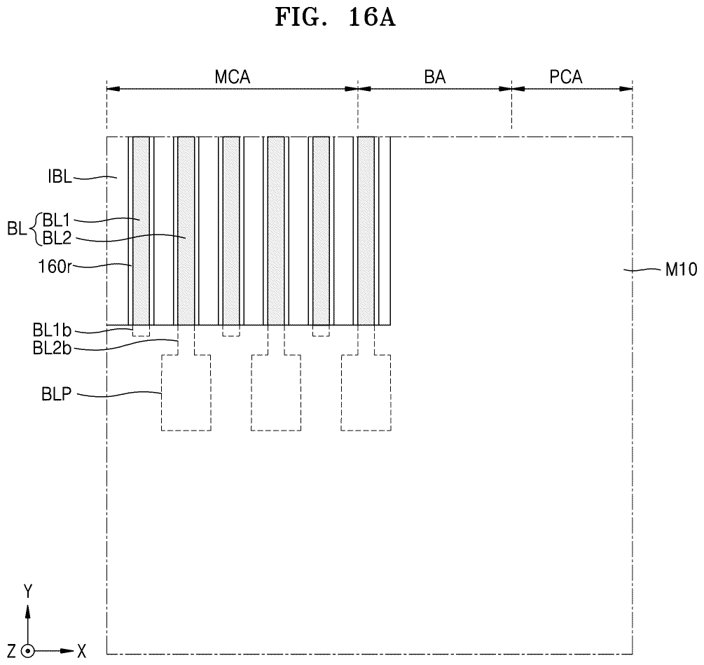

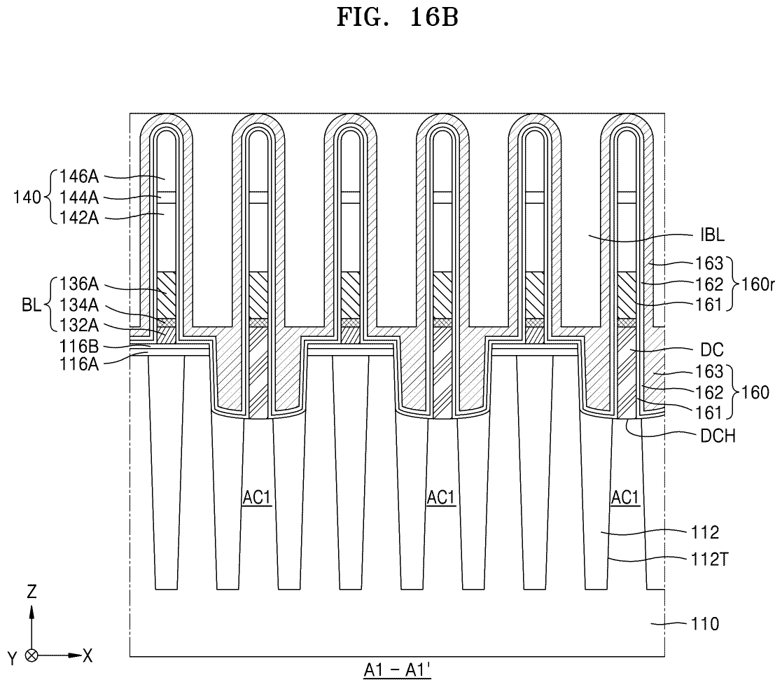

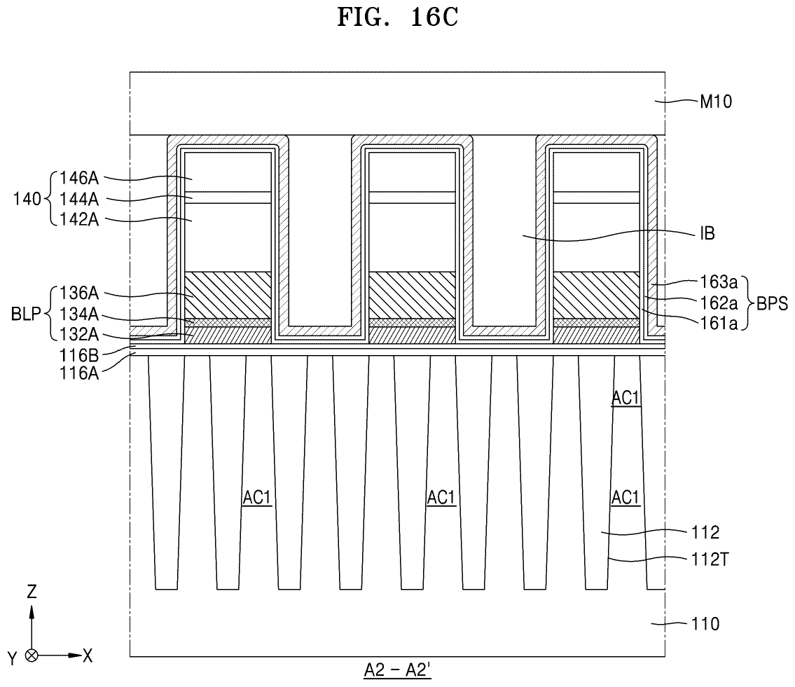

Referring to FIGS. 16A to 16C, a mask pattern M10 may be formed on the buried insulating layer IBL in the boundary area BA and the peripheral circuit area PCA. The mask pattern M10 may at least partially expose therethrough the buried insulating layer IBL and the insulating capping structure 140 in the cell array area MCA by not covering the same.

In some embodiments, as shown in FIG. 16A, the mask pattern M10 may overlap the bit line pad BLP in the vertical direction (Z direction) to at least partially cover the bit line pad BLP and at least partially cover an end portion of the bit line BL (e.g., the second end portion BL1b of the first bit line BL1 and the second end portion BL2b of the second bit line BL2). In addition, the mask pattern M10 may at least partially cover the peripheral circuit area PCA.

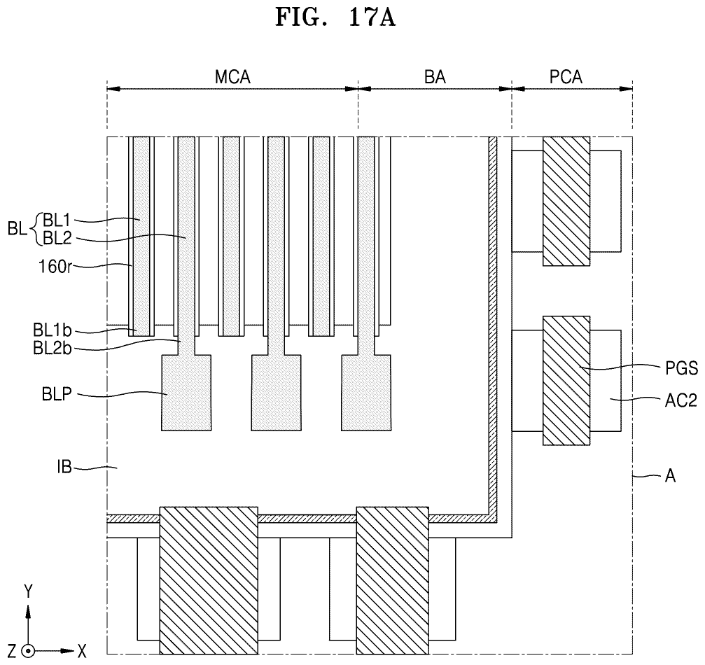

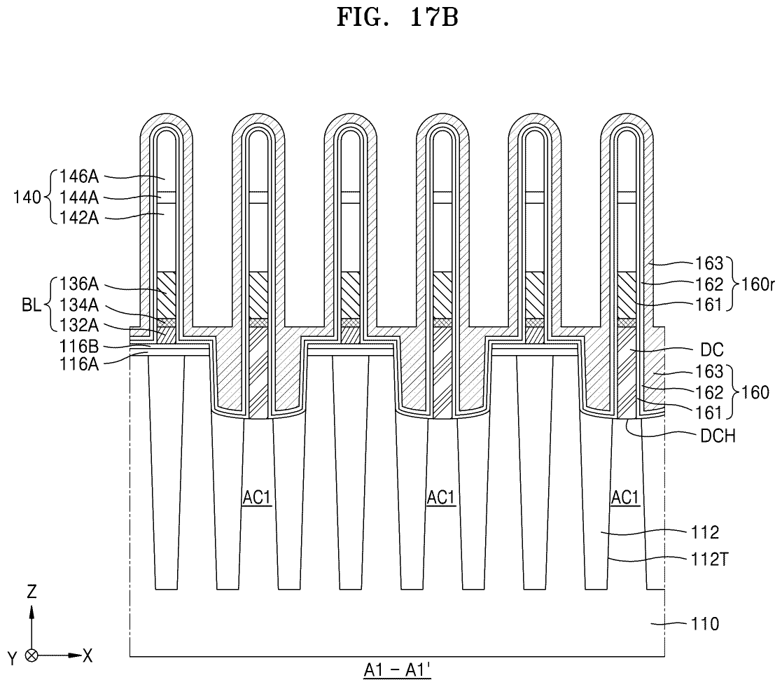

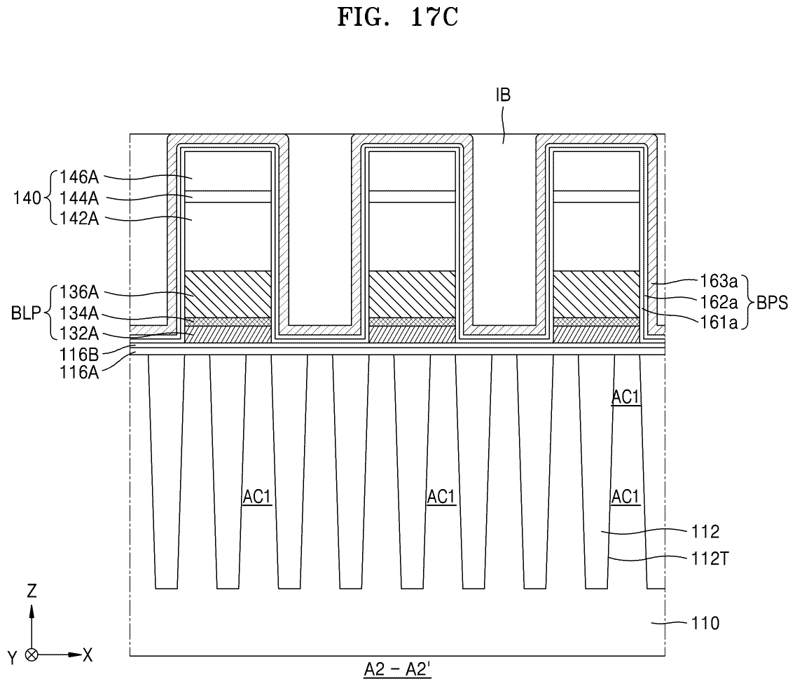

Referring to FIGS. 17A to 17C, the buried insulating layer IBL (see FIG. 16B) in the cell array area MCA, which is not covered by the mask pattern M10 (see FIG. 16A), may be removed to at least partially expose the space between two adjacent bit lines BL and the space between two adjacent insulating capping structures 140.

In some embodiments, after removing the buried insulating layer IBL (see FIG. 16B), the sidewalls of the liner structure 160r (e.g., the sidewalls of the third liner 163) on the sidewalls of the bit line BL and the sidewalls of the insulating capping structure 140 may be at least partially exposed again.

In some embodiments, a portion of the buried insulating layer IBL (see FIG. 16A) in the space between two adjacent bit line pads BLP or a portion of the buried insulating layer IBL (see FIG. 16A) between the bit line pad BLP and the peripheral circuit gate electrode PGS may remain without being removed. The portion of the buried insulating layer IBL (see FIG. 16A) remaining in the space between two adjacent bit line pads BLP or between the bit line pad BLP and the peripheral circuit gate electrode PGS may be referred to as the insulating block IB.

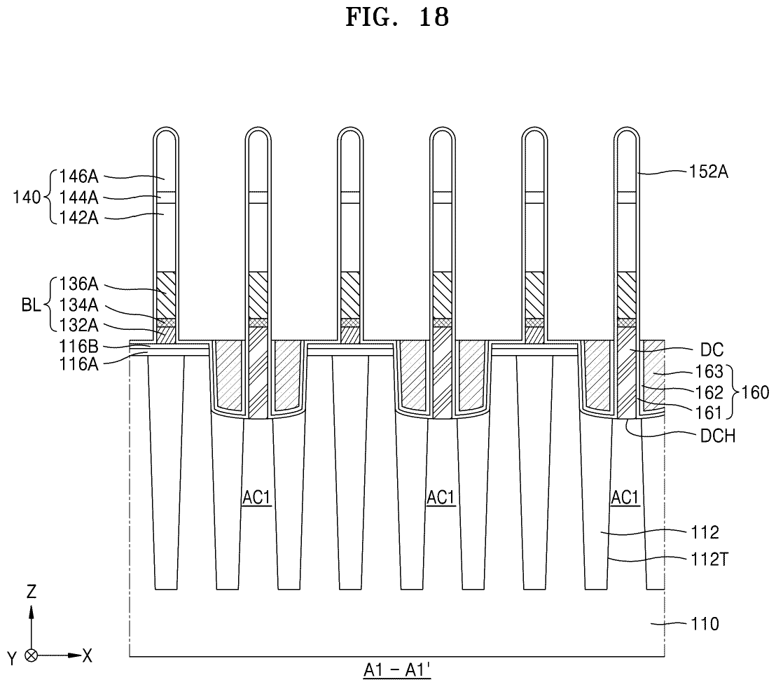

Referring to FIG. 18, the second liner 162 and the third liner 163 on the sidewalls of the bit line BL may be removed. By removing the second liner 162 and the third liner 163, the first liner 161 on the sidewalls of the bit line BL may be at least partially exposed.

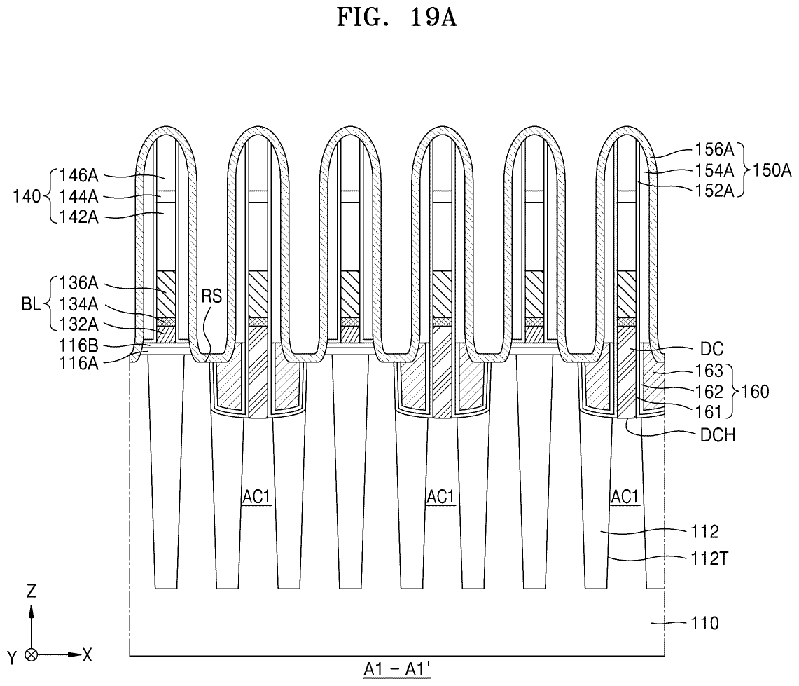

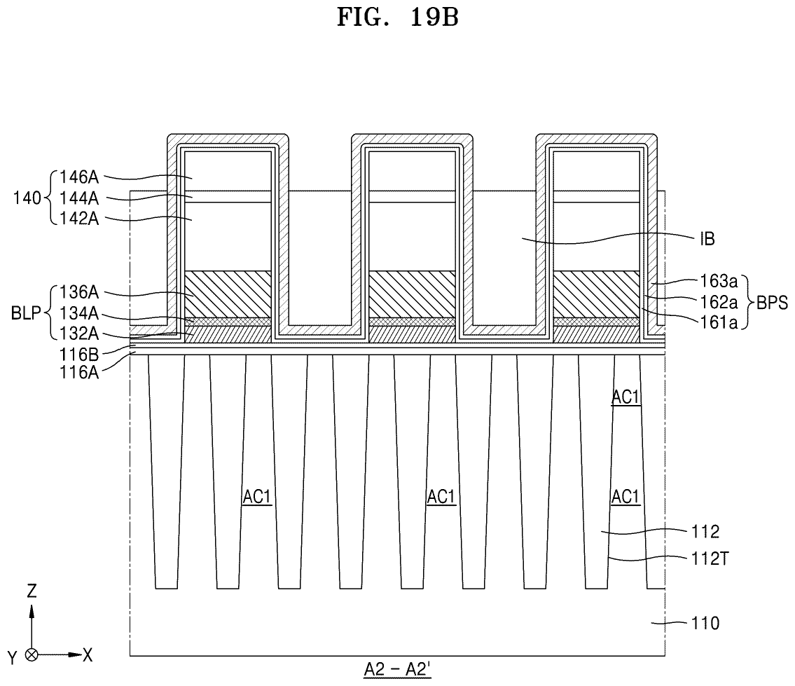

Referring to FIGS. 19A and 19B, the second spacer layer 154A may be formed on a sidewall of the bit line BL. In some embodiments, the second spacer layer 154A may include silicon oxide.

Thereafter, the first and second buffer insulating layers 116A and 116B may be removed from the space between two adjacent bit lines BL to at least partially expose the upper surface of the substrate 110. In a process of removing the first and second buffer insulating layers 116A and 116B, a portion of the substrate 110 and a portion of the bit line contact spacer 160 may also be removed to form a recess RS.

Thereafter, the third spacer layer 156A may be formed on the second spacer layer 154A. In some embodiments, the third spacer layer 156A may include silicon nitride or silicon oxynitride.

Herein, the first liner 161 on the sidewall of the bit line BL may be referred to as the first spacer layer 152A, and the first spacer layer 152A, the second spacer layer 154A, and the third spacer layer 156A may be collectively referred to as the bit line spacer 150A.

A method of removing the second liner 162 and then forming the second spacer layer 154A on a sidewall of the first liner 161 has been illustrated with reference to FIGS. 18, 19A, and 19B. However, in some embodiments, unlike described above, the second liner 162 may not be removed and the second spacer layer 154A may be further formed on a sidewall of the second liner 162. In some embodiments, the second liner 162 may not be removed and the second spacer layer 154A may not be formed, and in this case, the second liner 162 on the sidewall of the bit line BL may be referred to as the second spacer layer 154A.

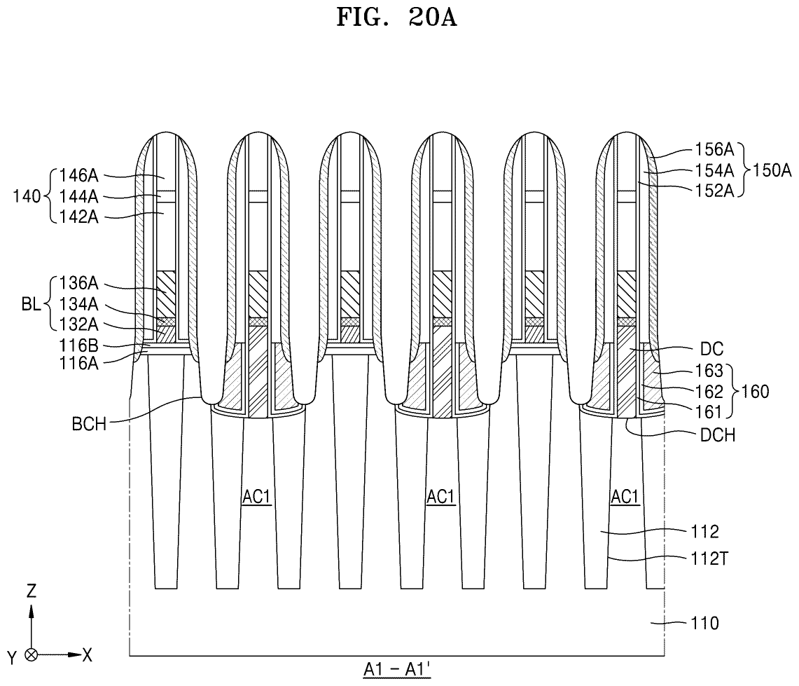

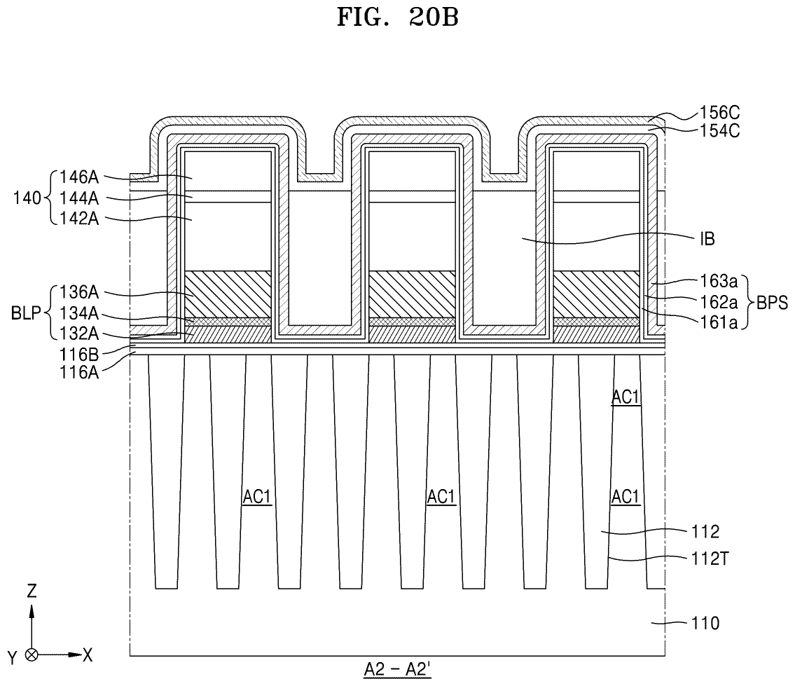

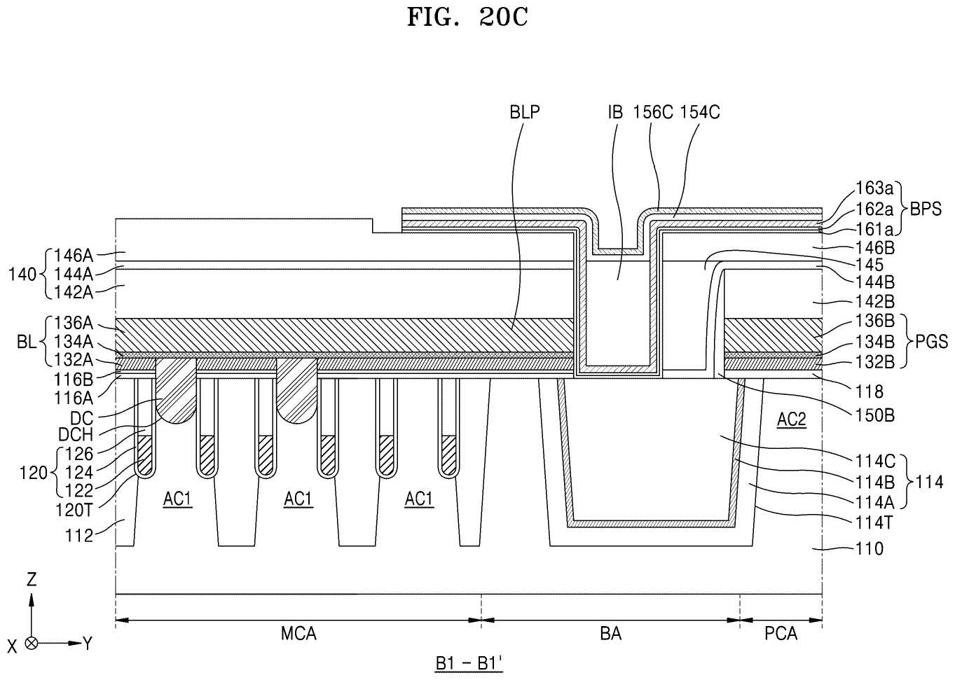

In some embodiments, in a process of forming the second spacer layer 154A and the third spacer layer 156A, the second spacer layer 154A and the third spacer layer 156A may be further formed on the bit line pad BLP and in the peripheral circuit area PCA. The second spacer layer 154A and the third spacer layer 156A remaining on the bit line pad BLP and in the peripheral circuit area PCA may be referred to as the first insulating capping layer 154C (see FIG. 20B) and the second insulating capping layer 156C (see FIG. 20B), respectively.

In some embodiments, in a process of exposing the upper surface of the substrate 110, a portion of an upper side of the insulating block IB may also be removed, thereby decreasing the level of the upper surface of the insulating block IB. In addition, in the process of exposing the upper surface of the substrate 110, the second liner 162 and/or the third liner 163 on the bit line pad BLP may be removed.

Referring to FIGS. 20A to 20C, an anisotropic etching process may be performed on the third spacer layer 156A to expose the upper surface of the substrate 110 (e.g., the first active area AC1) again, and an exposed portion of the upper side of the substrate 110 may be removed to extend the recess RS downward, thereby forming the buried contact hole BCH extending to the substrate 110.

In some embodiments, a process of forming the buried contact hole BCH may include a wet etching process, a dry etching process, or a combination thereof. In an etching process of forming the buried contact hole BCH, a portion of an upper side of the third spacer layer 156A may also be removed, such that the third spacer layer 156A has a shape tapered upward.

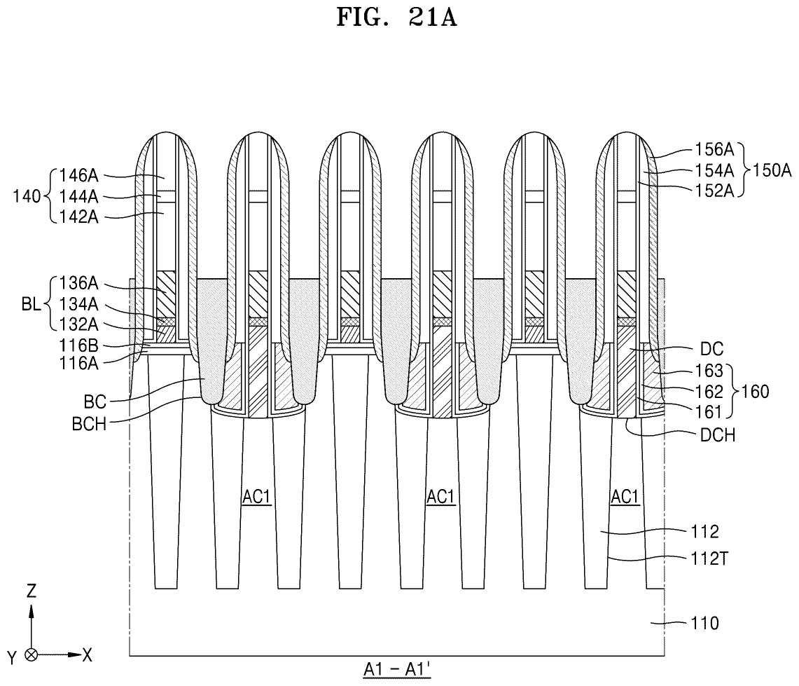

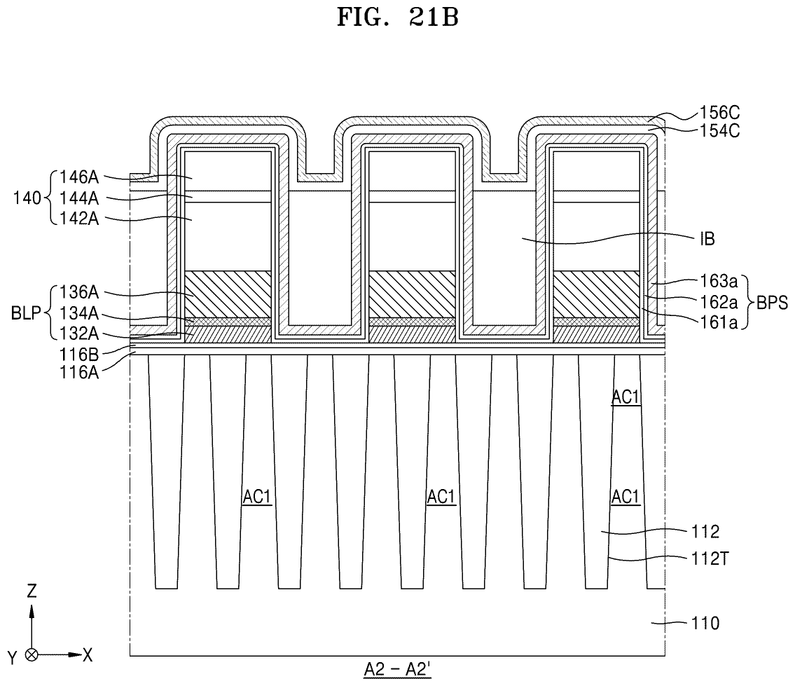

Referring to FIGS. 21A and 21B, a buried contact BC at least partially filling the inside of the buried contact hole BCH may be formed. In some embodiments, the buried contact BC may be formed using doped polysilicon.

In some embodiments, the buried contact hole BCH may be formed to have a line-type planar shape between two adjacent bit lines BL (e.g., between two adjacent bit line spacers 140), and then a preliminary contact layer having the line-type planar shape may be formed in the buried contact hole BCH and patterned to form the buried contact BC. Thereafter, an insulating fence may be formed in the space (e.g., a space from which a portion of the preliminary contact layer is removed) between two adjacent buried contacts BC by using an insulating material.

In some embodiments, a plurality of insulating fences may be formed between two adjacent bit lines BL and at intersection points of the plurality of word line trenches 120T by using an insulating material before forming the buried contact hole BCH, the buried contact hole BCH may be formed by removing a portion of the substrate 110 between the plurality of bit lines BL and between the plurality of insulating fences, and then the buried contact BC may be formed in the buried contact hole BCH.

Referring back to FIGS. 1 to 8, a conductive layer may be formed on the upper surfaces of the plurality of buried contacts BC and patterned to form the landing pad LP. Thereafter, the insulating pattern 170 at least partially surrounding the landing pad LP may be formed. The insulating pattern 170 may at least partially cover the sidewalls of the plurality of landing pads LP.

A plurality of lower electrodes 182 respectively electrically connected to the plurality of landing pads LP may be formed, and the capacitor dielectric layer 184 and the upper electrode 186 may be sequentially formed on a sidewall of each of the plurality of lower electrodes 182.

The semiconductor device 100 may be manufactured by performing the method described above.

According to some embodiments, the boundary spacer BPS and the insulating block IB may be in the space between two adjacent bit line pads BLP, and an end portion of the bit line BL may be at least partially covered by the insulating block IB so as not to be exposed in an etching process of forming the buried contact hole BCH. Therefore, a void defect that the bit line BL is removed by local erosion of the bit line spacer 150A may be prevented.

While the inventive concept has been particularly shown and described with reference to embodiments thereof, it will be understood that various changes in form and details may be made therein without departing from the spirit and scope of the inventive concept as set forth in the following claims.

What is claimed is:

1. A semiconductor device comprising:
a substrate comprising a first active area;
a plurality of bit lines on the substrate, intersecting with the first active area, extending in a first direction parallel to an upper surface of the substrate, and each having a first width in a second direction that intersects with the first direction;
a plurality of bit line pads respectively connected to end portions of the plurality of bit lines and each having a second width that is greater than the first width in the second direction;
a boundary spacer on a sidewall of each of the plurality of bit line pads; and
an insulating block on a sidewall of the boundary spacer and between two adjacent bit line pads among the plurality of bit line pads.

2. The semiconductor device of claim 1, wherein the boundary spacer is between each of the plurality of bit line pads and the insulating block, and the boundary spacer is on a sidewall and a bottom surface of the insulating block.

3. The semiconductor device of claim 1, wherein the boundary spacer comprises a first liner, a second liner, and a third liner stacked sequentially on the sidewall of each of the plurality of bit line pads.

4. The semiconductor device of claim 3, wherein the first liner includes silicon nitride or silicon oxynitride, the second liner includes silicon oxide, and the third liner includes silicon nitride or silicon oxynitride.

5. The semiconductor device of claim 1, wherein the boundary spacer is on the upper surface of the substrate, and the boundary spacer is between a bottom surface of the insulating block and the upper surface of the substrate.

6. The semiconductor device of claim 1, wherein the plurality of bit lines comprise a plurality of first bit lines and a plurality of second bit lines alternately arranged in the second direction, the plurality of first bit lines comprise first end portions and second end portions opposite to the first end portions of the plurality of first bit lines, the plurality of second bit lines comprise first end portions adjacent to the first end portions of the plurality of first bit lines and second end portions opposite to the first end portions of the plurality of second bit lines, and the plurality of bit line pads comprise a plurality of first bit line pads electrically connected to the first end portions of the plurality of first bit lines, respectively, and a plurality of second bit line pads electrically connected to the second end portions of the plurality of second bit lines, respectively.

7. The semiconductor device of claim 6, wherein the insulating block is in a space between two adjacent second bit line pads among the plurality of second bit line pads and between the second end portion of the first bit line and the second bit line pad.

8. The semiconductor device of claim 7, wherein the boundary spacer is between the second end portions of the plurality of first bit lines and the insulating block.

9. The semiconductor device of claim 1, wherein the substrate comprises a cell array area, a boundary area, and a peripheral circuit area, the semiconductor device further comprises a peripheral circuit gate electrode in the peripheral circuit area of the substrate, and at least a portion of the insulating block is between the bit line pad and the peripheral circuit gate electrode.

10. The semiconductor device of claim 9, wherein at least a portion of the boundary spacer is in the boundary area, and the at least a portion of the insulating block is on the at least a portion of the boundary spacer.

11. The semiconductor device of claim 1, wherein each of the plurality of bit line pads is integrally connected to a corresponding bit line.

12. A semiconductor device comprising:
a substrate comprising a first active area;
a plurality of bit lines on the substrate, intersecting with the first active area, extending in a first direction parallel to an upper surface of the substrate, and comprising a plurality of first bit lines and a plurality of second bit lines alternately arranged in a second direction that intersects with the first direction;
a plurality of bit line pads respectively connected to end portions of the plurality of bit lines and comprising a plurality of first bit line pads respectively connected to first end portions of the plurality of first bit lines and a plurality of second bit line pads respectively connected to second end portions opposite to first end portions of the plurality of second bit lines;
a boundary spacer on a sidewall of each of the plurality of bit line pads; and
an insulating block on a sidewall of the boundary spacer and between two adjacent bit line pads among the plurality of bit line pads.

13. The semiconductor device of claim 12, wherein the insulating block is between two adjacent second bit line pads among the plurality of second bit line pads, and the insulating block is in a space between a second end portion opposite to a first end portion of each first bit line and an adjacent second bit line pad of the plurality of second bit line pads.

14. The semiconductor device of claim 13, wherein the boundary spacer is between the second end portions of the plurality of first bit lines and the insulating block.

15. The semiconductor device of claim 12, wherein each of the plurality of bit line pads is integrally connected to a corresponding bit line, each of the plurality of bit lines has a first width in the second direction, and each of the plurality of bit line pads has a second width that is greater than the first width in the second direction.

16. The semiconductor device of claim 12, wherein the boundary spacer comprises a first liner, a second liner, and a third liner stacked sequentially on the sidewall of each of the plurality of bit line pads, and the third liner is in contact with the insulating block.

17. The semiconductor device of claim 12, wherein the substrate comprises a cell array area, a boundary area, and a peripheral circuit area, at least a portion of the boundary spacer is in the boundary area, and at least a portion of the insulating block is on the at least a portion of the boundary spacer.

18. A semiconductor device comprising:
a substrate comprising a cell array area, a boundary area, and a peripheral circuit area and comprising a first active area in the cell array area;
a boundary insulating structure in the boundary area of the substrate;
a plurality of bit lines disposed in the cell array area of the substrate, intersecting with the first active area, extending in a first direction parallel to an upper surface of the substrate, and each having a first width in a second direction that intersects with the first direction;
a plurality of bit line pads respectively connected to end portions of the plurality of bit lines and each having a second width that is greater than the first width in the second direction;
a boundary spacer on a sidewall of each of the plurality of bit line pads;
a peripheral circuit gate electrode in the peripheral circuit area of the substrate; and
an insulating block on a sidewall of the boundary spacer, between two adjacent bit line pads among the plurality of bit line pads, and between each of the plurality of bit line pads and the peripheral circuit gate electrode.

19. The semiconductor device of claim 18, wherein the boundary spacer comprises a first liner, a second liner, and a third liner stacked sequentially on the sidewall of each of the plurality of bit line pads, and the third liner is in contact with the insulating block.

20. The semiconductor device of claim 18, wherein the plurality of bit lines comprise a plurality of first bit lines and a plurality of second bit lines alternately arranged in the second direction, the plurality of first bit lines comprise first end portions and second end portions opposite to the first end portions of the plurality of first bit lines, the plurality of second bit lines comprise first end portions adjacent to the first end portions of the plurality of first bit lines and second end portions opposite to the first end portions of the plurality of second bit lines, the plurality of bit line pads comprise a plurality of first bit line pads electrically connected to the first end portions of the plurality of first bit lines, respectively, and a plurality of second bit line pads electrically connected to the second end portions of the plurality of second bit lines, respectively, and the insulating block is in a space between two adjacent second bit line pads among the plurality of second bit line pads and between a second end portion of a first bit line of the plurality of first bit lines and a second bit line pad of the plurality of second bit line pads.
